(19) United States
(12) Patent Application Publication
(10) Pub. No.: US 2024/0313077 A1
(43) Pub. Date: Sep. 19, 2024

(54) SEMICONDUCTOR DEVICE

(71) Applicant: Samsung Electronics Co., Ltd., Suwon-si (KR)

(72) Inventors: Chulsung KIM, Suwon-si (KR); Yeonghan GWON, Suwon-si (KR); Jinkyung SON, Suwon-si (KR); Jaepo LIM, Suwon-si (KR)

(73) Assignee: Samsung Electronics Co., Ltd., Suwon-si (KR)

(21) Appl. No.: 18/537,536

(22) Filed: Dec. 12, 2023

(30) Foreign Application Priority Data
Mar. 14, 2023 (KR) 10-2023-0033390

(51) Int. Cl. H01L 29/423; H01L 29/06; H01L 29/08; H01L 29/417; H01L 29/66; H01L 29/775

(52) U.S. Cl. CPC H01L 29/42392; H01L 29/0673; H01L 29/0847; H01L 29/41733; H01L 29/66439; H01L 29/775

(57) ABSTRACT

Disclosed is a semiconductor device comprising a substrate including an active pattern, a channel pattern on the active pattern and including semiconductor patterns that are vertically stacked and spaced apart from each other, a source/drain pattern connected to the semiconductor patterns, a gate electrode on the semiconductor patterns and including inner electrodes between neighboring semiconductor patterns and an outer electrode on an uppermost semiconductor pattern, and a capping pattern on a top surface of the outer electrode. A line-width of the outer electrode is a first width. The outer electrode has a first height. The first height is equal to or less than the first width.

### CROSS-REFERENCE TO RELATED APPLICATION

This U.S. nonprovisional application claims priority under 35 U.S.C § 119 to Korean Patent Application No. 10-2023-0033390 filed on Mar. 14, 2023 in the Korean Intellectual Property Office, the disclosure of which is hereby incorporated by reference in its entirety.

### BACKGROUND

The present inventive concepts relate to a semiconductor devices, and more particularly, to semiconductor devices including a field effect transistor.

A semiconductor device includes an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various studies have been conducted to develop methods of fabricating semiconductor devices having superior performances while overcoming limitations caused by high integration of the semiconductor devices.

### SUMMARY

Some example embodiments of the present inventive concepts provide a semiconductor device with increased reliability.

Some example embodiments of the present inventive concepts provide a semiconductor device with improved electrical properties.

According to some example embodiments of the present inventive concepts, a semiconductor device may include a substrate including an active pattern, a channel pattern on the active pattern, the channel pattern including a plurality of semiconductor patterns that are vertically stacked and spaced apart from each other, a source/drain pattern connected to the plurality of semiconductor patterns, a gate electrode on the plurality of semiconductor patterns, the gate electrode including a plurality of inner electrodes between neighboring ones of the plurality of semiconductor patterns and an outer electrode on an uppermost semiconductor pattern, and a capping pattern on a top surface of the outer electrode. A line-width of the outer electrode may be a first width. The outer electrode may have a first height. The first height may be equal to or less than the first width.

According to some example embodiments of the present inventive concepts, a semiconductor device may include a substrate including an active pattern, a channel pattern on the active pattern, the channel pattern including a plurality of semiconductor patterns that are vertically stacked and spaced apart from each other, a source/drain pattern connected to the plurality of semiconductor patterns, a gate electrode on the plurality of semiconductor patterns, the gate electrode including a plurality of inner electrodes that are between neighboring ones of the plurality of semiconductor patterns, a gate structure on an uppermost semiconductor pattern from among the semiconductor patterns, and a capping pattern on the gate structure. The gate structure may include an outer electrode on the uppermost semiconductor pattern, a gate dielectric layer between the uppermost semiconductor pattern and the outer electrode, the gate dielectric layer extending to a lateral surface of the outer electrode, and a gate spacer on a lateral surface of the gate dielectric layer. The gate structure and the capping pattern may be misaligned with each other.

According to some example embodiments of the present inventive concepts, a semiconductor device may include a substrate including an active pattern, a device isolation layer defining the active pattern, a channel pattern on the active pattern, the channel pattern including a plurality of semiconductor patterns that are vertically stacked and spaced apart from each other, a source/drain pattern connected to the plurality of semiconductor patterns, a gate electrode on the plurality of semiconductor patterns, the gate electrode including a plurality of inner electrodes between neighboring ones of the plurality of semiconductor patterns and an outer electrode on an uppermost one of the semiconductor pattern, a gate dielectric layer between the gate electrode and each of neighboring ones of the semiconductor patterns, a gate spacer on a sidewall of the gate electrode, a capping pattern on a top surface of the outer electrode, an active contact electrically connected to the source/drain pattern, a metal-semiconductor compound layer between the active contact and the source/drain pattern, a first metal layer on the capping pattern, the first metal layer including a power line and a first wiring line electrically connected to the active contact, and a second metal layer on the first metal layer, the second metal layer including a second wiring line electrically connected to first metal layer. A top surface of the capping pattern and a top surface of the active contact may be substantially coplanar with each other. A second height of the capping pattern may be equal to or greater than a first height of the outer electrode.

### BRIEF DESCRIPTION OF DRAWINGS

FIGS. 1 to 3 illustrate conceptual views showing logic cells of a semiconductor device according to some example embodiments of the present inventive concepts.

FIG. 4 illustrates a plan view showing a semiconductor device according to an example embodiment of the present inventive concepts.

FIGS. 5A, 5B, 5C, and 5D illustrate cross-sectional views respectively taken along lines A-A′, B-B′, C-C′, and D-D′ of FIG. 4.

FIGS. 6A to 6C illustrate cross-sectional views showing semiconductor devices according to some example embodiments of the present inventive concepts.

FIGS. 7A, 7B, 8A, 8B, 9A, 9B, 9C, 10A, 10B, 10C, 11A, 11B, 11C, 11D, 12A, 12B, 12C, 13A, 13B, 13C, 13D, 14A, 14B, and 14C illustrate cross-sectional views showing a method of fabricating a semiconductor device according to an example embodiment of the present inventive concepts.

### DETAILED DESCRIPTION

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

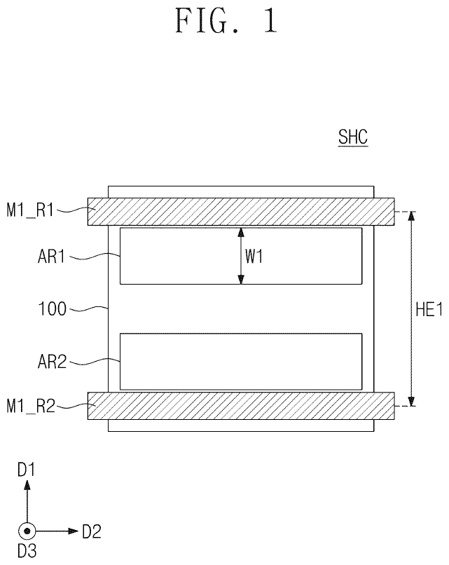

FIGS. 1 to 3 illustrate conceptual views showing logic cells of a semiconductor device according to some example embodiments of the present inventive concepts.

Referring to FIG. 1, a single height cell SHC may be provided. For example, a substrate 100 may be provided thereon with a first power line M1_R1 and a second power line M1_R2. The first power line M1_R1 may be a path for providing a source voltage VSS, for example, a ground voltage. The second power line M1_R2 may be a path for providing a drain voltage VDD, for example, a power voltage.

The single height cell SHC may be defined between the first power line M1_R1 and the second power line M1_R2. The single height cell SHC may include one first active region AR1 and one second active region AR2. One of the first and second active regions AR1 and AR2 may be a PMOSFET region, and the other of the first and second active regions AR1 and AR2 may be an NMOSFET region. For example, the single height cell SHC may have a complementary metal oxide semiconductor (CMOS) structure provided between the first power line M1_R1 and the second power line M1_R2.

The first and second active regions AR1 and AR2 may extend in a second direction D2. A first height HE1 may be defined to indicate a length in the first direction D1 of the single height cell SHC. A first height HE1 may be substantially the same as a distance (e.g., pitch) between the first power line M1_R1 and the second power line M1_R2.

The single height cell SHC may constitute one logic cell. In this description, the logic cell may mean a logic device, such as AND, OR, XOR, XNOR, and inverter, that performs a specific function. For example, the logic cell may include transistors for constituting a logic device, and may also include wiring lines that connect the transistors to each other.

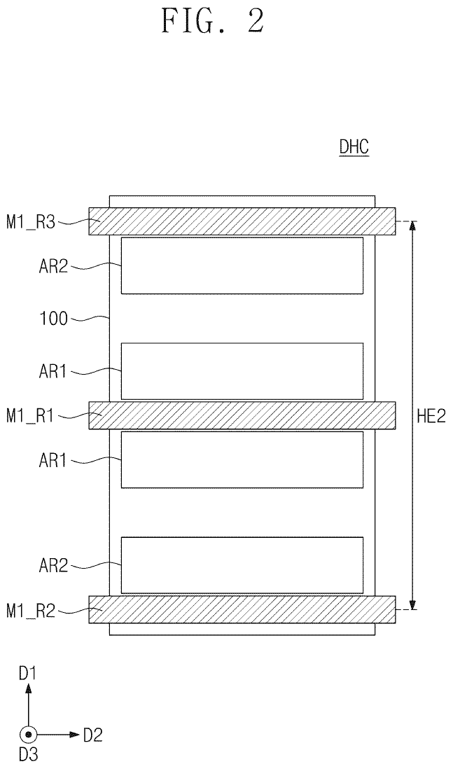

Referring to FIG. 2, a double height cell DHC may be provided. For example, a substrate 100 may be provided thereon with a first power line M1_R1, a second power line M1_R2, and a third power line M1_R3. The first power line M1_R1 may be disposed between the second power line M1_R2 and the third power line M1_R3. The third power line M1_R3 may be a path for providing a source voltage VSS.

The double height cell DHC may be defined between the second power line M1_R2 and the third power line M1_R3. The double height cell DHC may include two first active regions AR1 and two second active regions AR2.

One of the two second active regions AR2 may be adjacent to the second power line M1_R2. The other of the two second active regions AR2 may be adjacent to the third power line M1_R3. The two first active regions AR1 may be adjacent to the first power line M1_R1. When viewed in plan, the first power line M1_R1 may be disposed between the two first active regions AR1.

A second height HE2 may be defined to indicate a length in the first direction D1 of the double height cell DHC. The second height HE2 may be about twice the first height HE1 of FIG. 1. The two first active regions AR1 of the double height cell DHC may be collectively connected together to act as one active region.

In the present disclosure, the double height cell DHC shown in FIG. 2 may be referred to as a multi-height cell. Although not shown, the multi-height cell may include a triple height cell whose cell height is about three times that of the single height cell SHC.

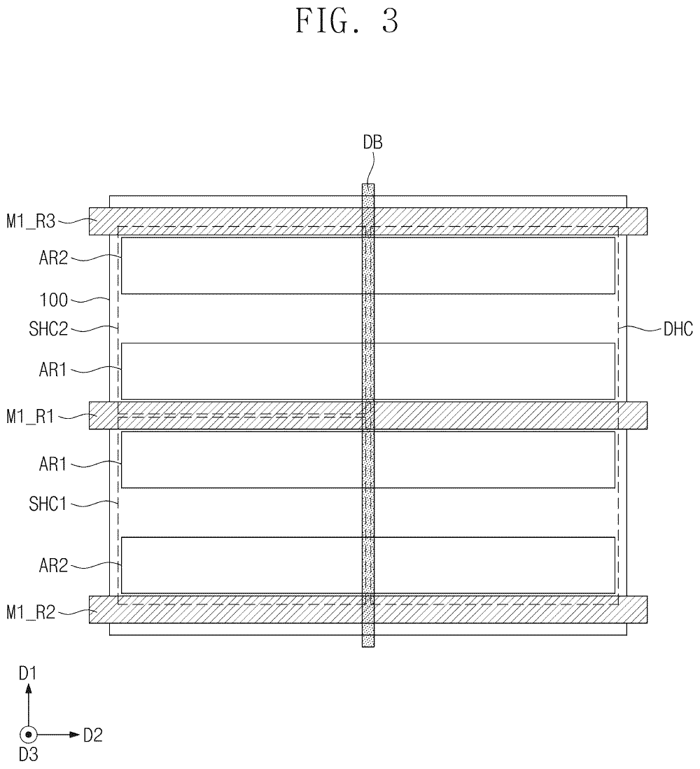

Referring to FIG. 3, a substrate 100 may be provided thereon with a first single height cell SHC1, a second single height cell SHC2, and a double height cell DHC that are two-dimensionally disposed. The first single height cell SHC1 may be disposed between a first power line M1_R1 and a second power line M1_R2. The second single height cell SHC2 may be disposed between the first power line M1_R1 and a third power line M1_R3. The second single height cell SHC2 may be adjacent in a first direction D1 to the first single height cell SHC1.

The double height cell DHC may be disposed between the second power line M1_R2 and the third power line M1_R3. The double height cell DHC may be adjacent in a second direction D2 to the first and second single height cells SHC1 and SHC2.

A separation structure DB may be provided between the first single height cell SHC1 and the double height cell DHC and between the second single height cell SHC2 and the double height cell DHC. The separation structure DB may electrically separate an active region of the double height cell DHC from an active region of each of the first and second single height cells SHC1 and SHC2.

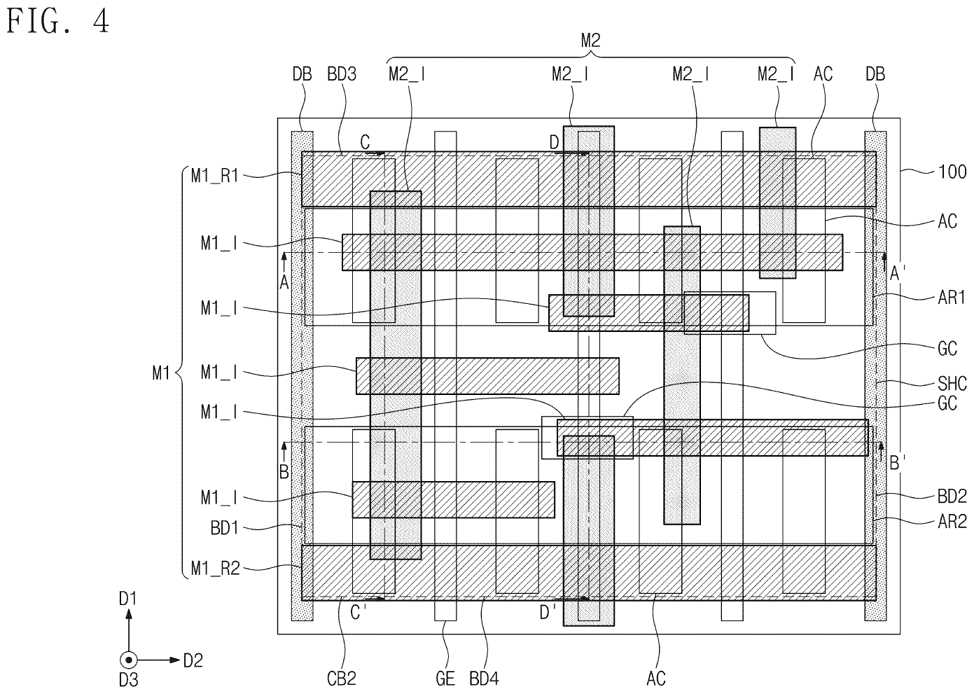

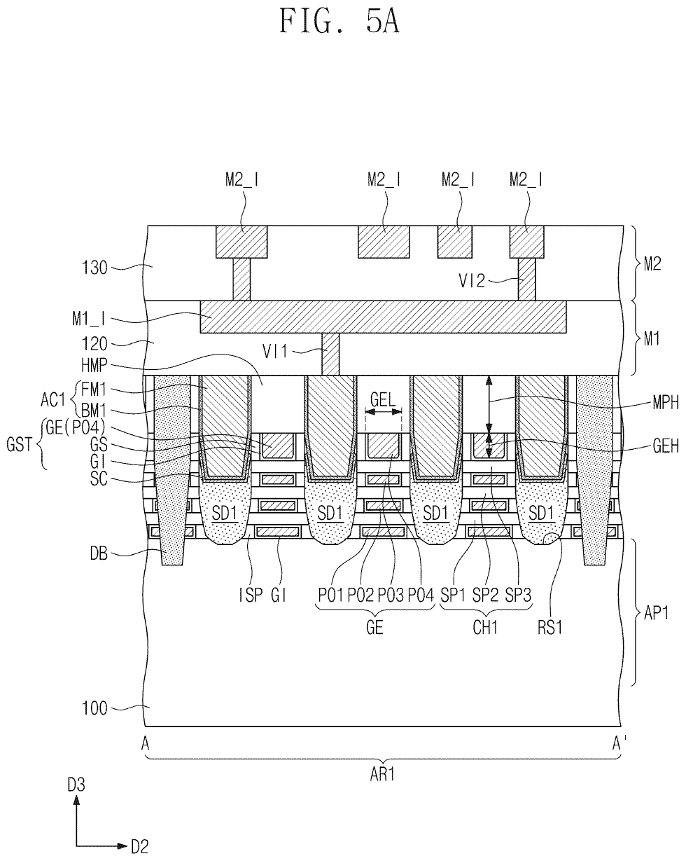

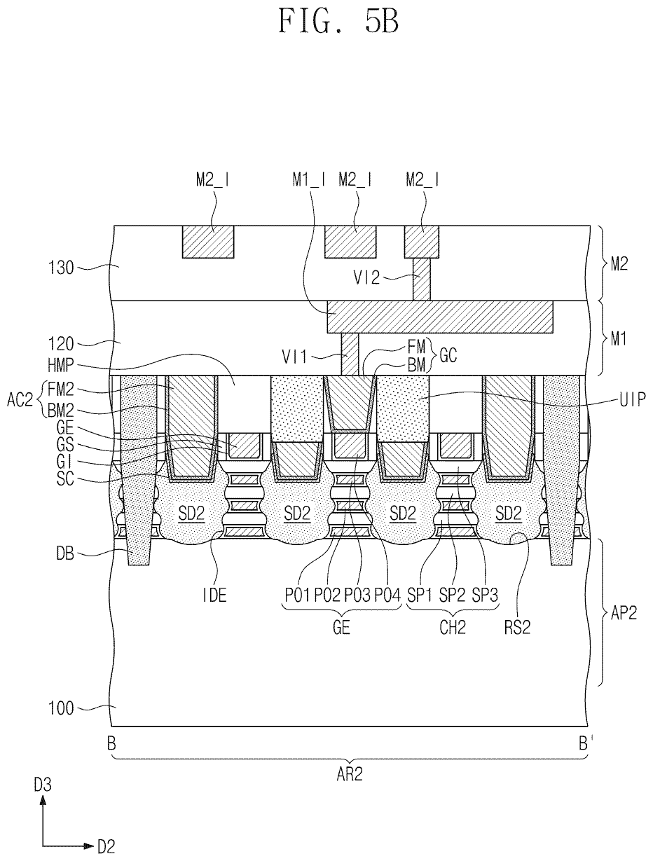

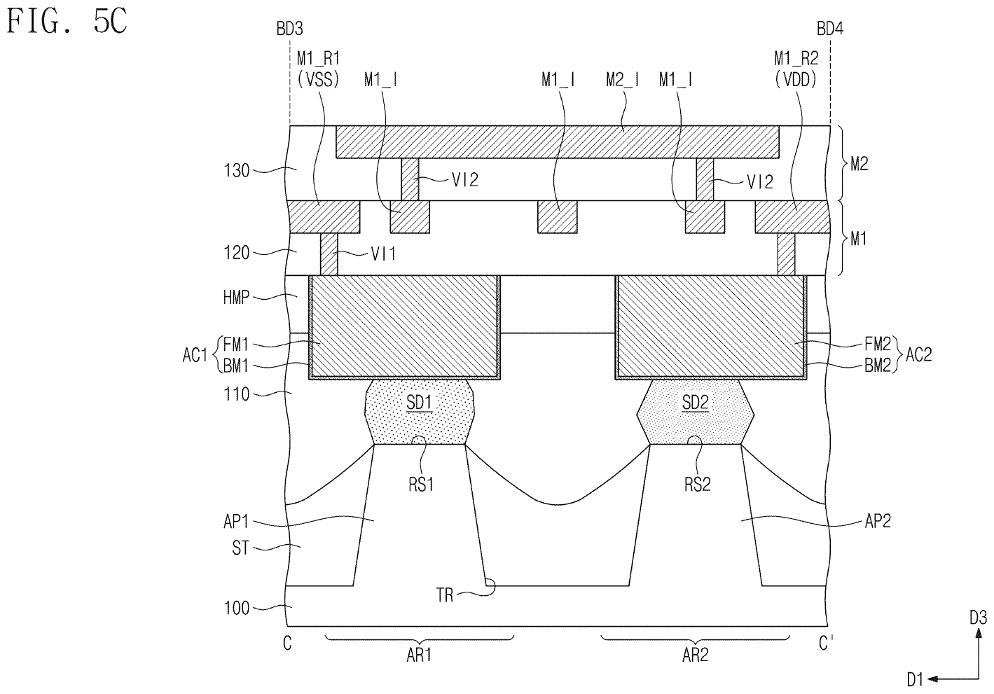

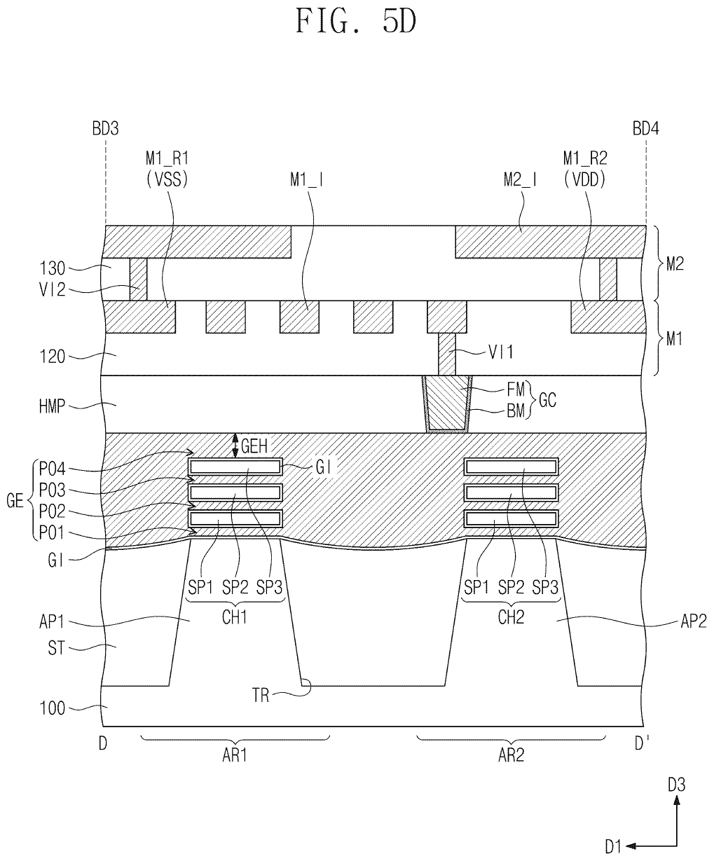

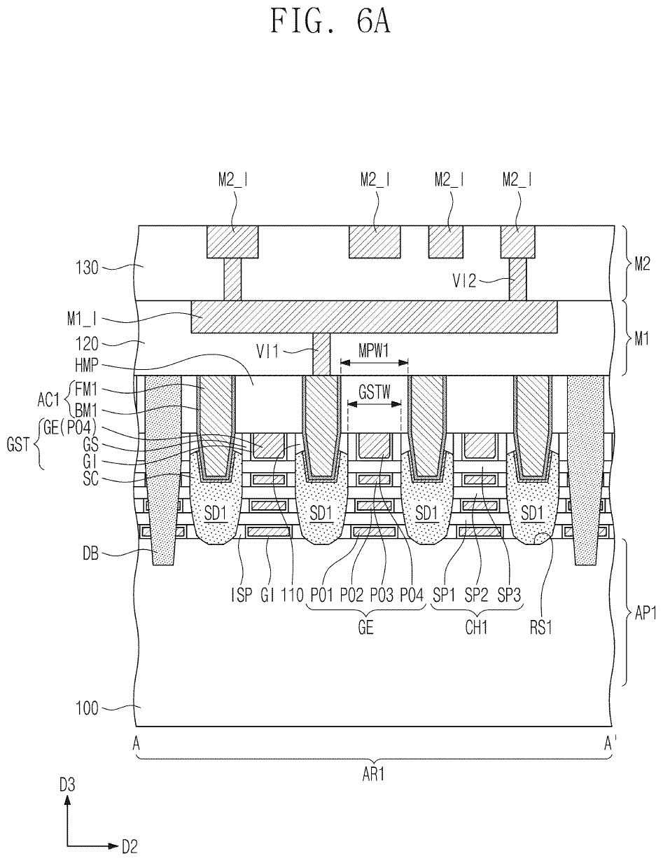

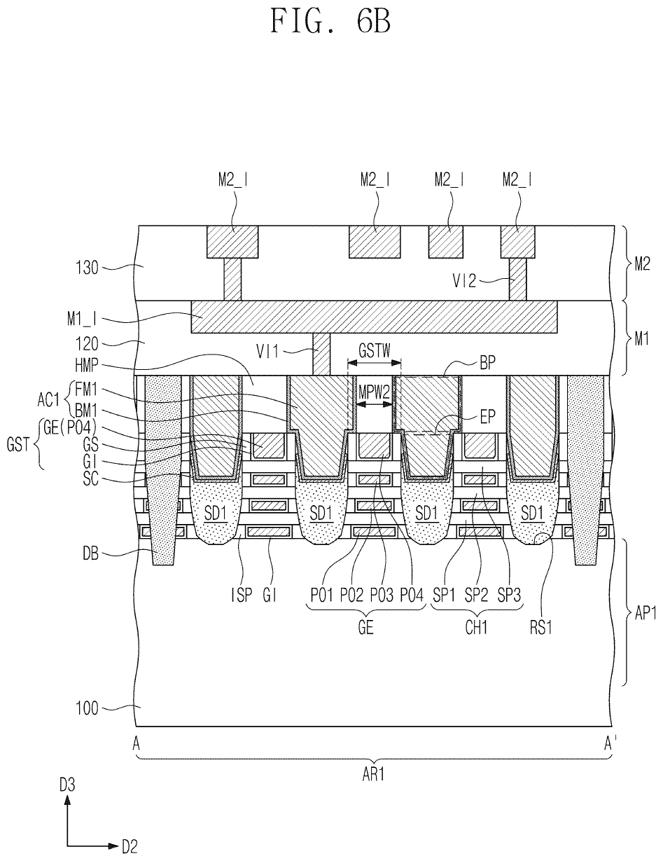

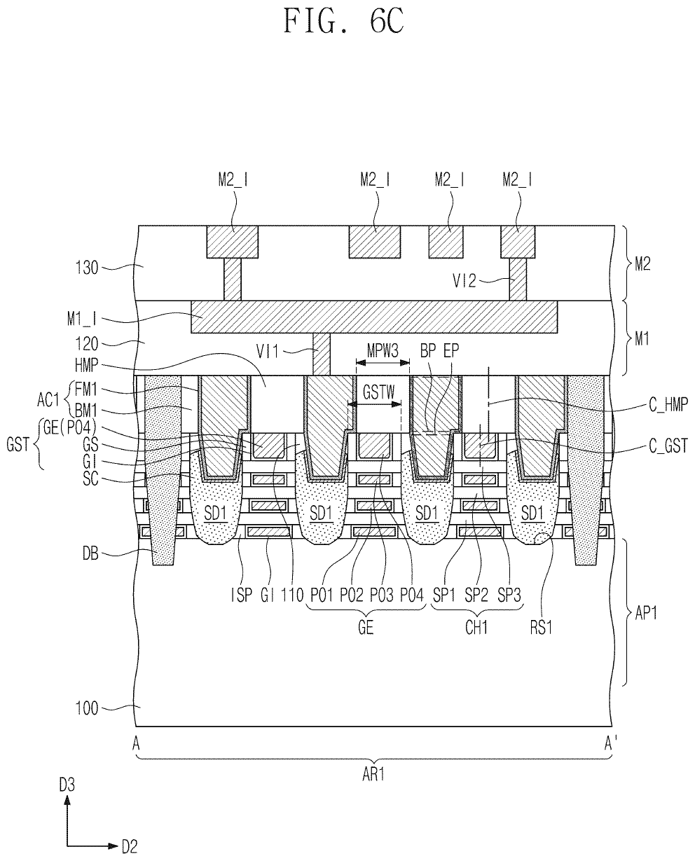

FIG. 4 illustrates a plan view showing a semiconductor device according to an example embodiment of the present inventive concepts. FIGS. 5A, 5B, 5C, and 5D illustrate cross-sectional views respectively taken along lines A-A′, B-B′, C-C′, and D-D′of FIG. 4. FIGS. 6A to 6C illustrate cross-sectional views showing semiconductor devices according to some example embodiments of the present inventive concepts, corresponding to that of FIG. 5A. A semiconductor device depicted in FIGS. 4 and 5A to 5D is a detailed example of the single height cell SHC shown in FIG. 1.

Referring to FIGS. 4 and 5A to 5D, a single height cell SHC may be provided on a substrate 100. The single height cell SHC may be provided thereon with logic transistors included in a logic circuit. The substrate 100 may be a compound semiconductor substrate or a semiconductor substrate including silicon, germanium, or silicon-germanium. For example, the substrate 100 may be a silicon substrate.

The substrate 100 may include a first active region AR1 and a second active region AR2. Each of the first and second active regions AR1 and AR2 may extend in a second direction D2. In an example embodiment, the first active region AR1 may be an NMOSFET region, and the second active region AR2 may be a PMOSFET region.

A first active pattern AP1 and a second active pattern AP2 may be defined by a trench TR formed on an upper portion of the substrate 100. The first active pattern AP1 may be provided on the first active region AR1, and the second active pattern AP2 may be provided on the second active region AR2. The first and second active patterns AP1 and AP2 may extend in the second direction D2. The first and second active patterns AP1 and AP2 may be vertically protruding portions of the substrate 100.

A device isolation layer ST may be provided on the substrate 100. The device isolation layer ST may fill the trench TR. The device isolation layer ST may include a silicon oxide layer. The device isolation layer ST may not cover any of first and second channel patterns CH1 and CH2 which will be discussed below.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in a vertical direction (or a third direction D3).

Each of the first, second, and third semiconductor patterns SP1, SP2, and SP3 may include silicon (Si), germanium (Ge), or silicon-germanium (SiGe). For example, each of the first, second, and third semiconductor patterns SP1, SP2, and SP3 may include crystalline silicon (e.g., monocrystalline silicon). In an example embodiment of the present inventive concepts, the first, second, and third semiconductor patterns SP1, SP2, and SP3 may be stacked nano-sheets.

A plurality of first source/drain patterns SD1 may be provided on the first active pattern AP1. A plurality of first recesses RS1 may be formed on an upper portion of the first active pattern AP1. The first source/drain patterns SD1 may be provided in the first recesses RS1, respectively. The first source/drain patterns SD1 may be impurity regions of a first conductivity type (e.g., n-type). The first channel pattern CH1 may be interposed between a pair of first source/drain patterns SD1. For example, the pair of first source/drain patterns SD1 may be connected to each other through the stacked first, second, and third semiconductor patterns SP1, SP2, and SP3.

A plurality of second source/drain patterns SD2 may be provided on the second active pattern AP2. A plurality of second recesses RS2 may be formed on an upper portion of the second active pattern AP2. The second source/drain patterns SD2 may be provided in the second recesses RS2, respectively. The second source/drain patterns SD2 may be impurity regions of a second conductivity type (e.g., p-type). The second channel pattern CH2 may be interposed between a pair of second source/drain patterns SD2. For example, the pair of second source/drain patterns SD2 may be connected to each other through the stacked first, second, and third semiconductor patterns SP1, SP2, and SP3.

The first and second source/drain patterns SD1 and SD2 may be epitaxial patterns formed by a selective epitaxial growth (SEG) process. For example, each of the first and second source/drain patterns SD1 and SD2 may have a top surface (e.g., a portion of the top surface) higher than a top surface of the third semiconductor pattern SP3. For another example, at least one of the first and second source/drain patterns SD1 and SD2 may have a top surface at substantially the same level as that of a top surface of the third semiconductor pattern SP3.

In an example embodiment of the present inventive concepts, the first source/drain patterns SD1 may include the same semiconductor element (e.g., Si) as that of the substrate 100. The second source/drain patterns SD2 may include a semiconductor element (e.g., SiGe) whose lattice constant is greater than that of a semiconductor element of the substrate 100. Therefore, a pair of second source/drain patterns SD2 may provide the second channel pattern CH2 with compressive stress.

In an example embodiment of the present inventive concepts, the second source/drain pattern SD2 may have an uneven embossing shape on a sidewall thereof. For example, the sidewall of the second source/drain pattern SD2 may have a wave-shape profile. The sidewall of the second source/drain pattern SD2 may protrude toward first, second, and third inner electrodes PO1, PO2, and PO3 of a gate electrode GE, as discussed below.

The first and second channel patterns CH1 and CH2 may be provided thereon with gate electrodes GE. Etch of the gate electrodes GE may extend in a first direction D1, while running across the first and second channel patterns CH1 and CH2. Each of the gate electrodes GE may vertically overlap the first and second channel patterns CH1 and CH2. The gate electrodes GE may be arranged at a first pitch in the second direction D2.

The gate electrode GE may include a first inner electrode PO1 interposed between the first semiconductor pattern SP1 and the active pattern AP1 or AP2, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring to FIG. 5D, the gate electrode GE may surround a top surface, a bottom surface, and opposite sidewalls of each of the first, second, and third semiconductor patterns SP1, SP2, and SP3. For example, a transistor according to the present example embodiment may be a three-dimensional field effect transistor (e.g., Multi-Bridge-Channel FET (MBCFET) or Gate-All-Around FET (GAAFET)), in which the gate electrode GE three-dimensionally surrounds the first and second channel patterns CH1 and CH2.

Referring back to FIG. 5A, the outer electrode PO4 may have a line-width in the second direction D2 and a height in the third direction D3. The third direction D3 may be a direction that intersects all of the first and second directions D1 and D2. The third direction D3 may be a direction perpendicular to the substrate 100.

A line-width of the outer electrode PO4 may be defined as a first width GEL. For example, the first width GEL may be defined to indicate a length in the second direction D2 of the outer electrode PO4. The first width GEL may be a horizontal distance from one lateral surface of the outer electrode PO4 to another lateral surface of the outer electrode PO4. For example, the first width GEL may range from about 5.0 nm to about 30.0 nm.

A height of the outer electrode PO4 may be defined as a first height GEH. For example, the first height GEH may be defined to indicate a length in the third direction D3 of the outer electrode PO4. The first height GEH may be a vertical distance from a top surface of the third semiconductor pattern SP3 to an uppermost surface of the outer electrode PO4. For example, the first height GEH may range from about 5.0 nm to about 30.0 nm, for example, from about 10.0 nm to about 12.0 nm. The first height GEH may be equal to or less than the first width GEL.

On the first active region AR1, inner spacers ISP may be interposed between the first source/drain pattern SD1 and the first, second, and third inner electrodes PO1, PO2, and PO3 of the gate electrode GE, respectively. Each of the first, second, and third inner electrodes PO1, PO2, and PO3 of the gate electrode GE may be spaced apart from the first source/drain pattern SD1 across the inner spacer ISP. The inner spacer ISP may mitigate or prevent a leakage current from the gate electrode GE.

Referring back to FIGS. 4 and 5A to 5D, a pair of gate spacers GS may be disposed on opposite sidewalls of the outer electrode PO4 of the gate electrode GE. The gate spacers GS may extend in the first direction D1 along the gate electrode GE. The gate spacers GS may have their top surfaces coplanar with that of the outer electrode PO4 of the gate electrode GE. In an example embodiment, the gate spacers GS may include at least one selected from SiCN, SiCON, and SiN. In another example embodiment, the gate spacers GS may include a multiple layer formed of at least two selected from SiCN, SiCON, and SiN. In an example embodiment of the present inventive concepts, the gate spacer GS may include a silicon-containing dielectric material. The gate spacer GS may act as an etch stop layer when forming active contacts AC, which will be discussed below. The gate spacer GS may cause a self-alignment formation of the active contacts AC.

A capping pattern HMP may be provided on the gate electrode GE. For example, the capping pattern HMP may be provided on the outer electrode PO4. The capping pattern HMP may extend in the first direction D1 along the gate electrode GE. The capping pattern HMP may include a material having an etch selectivity with respect to a first interlayer dielectric layer 110, which will be discussed below. For example, the capping pattern HMP may include a material having an etch selectivity with respect to silicon oxide. The capping pattern HMP may include, for example, at least one selected from SiN, SiOC, SiOCN, SiCN, SiCON, TIN, WC, and a combination thereof.

Referring back to FIG. 5A, the capping pattern HMP may have a height in the third direction D3. A second height MPH may be defined to indicate the height of the capping pattern HMP. For example, the second height MPH may be defined to indicate a length in the third direction D3 of the capping pattern HMP. The second height MPH may be a vertical distance from a top surface of the outer electrode PO4 to an uppermost surface of the capping pattern HMP. For example, the second height MPH may range from about 5.0 nm to about 50.0 nm, for example, from about 10.0 nm to about 20.0 nm. The second height MPH of the capping pattern HMP may be equal to or greater than the first height GEH of the outer electrode PO4.

The capping pattern HMP may have a top surface substantially coplanar with that of each of first and second active contacts AC1 and AC2, which will be discussed below. For example, the top surface of the capping pattern HMP may be located at the same level as that of the top surface of each of the first and second active contacts AC1 and AC2. The capping pattern HMP may have a bottom surface in contact with a top surface of the outer electrode PO4, the top surface of the gate spacer GS, and a top surface of the gate dielectric layer GI, which will be discussed below. For example, the capping pattern HMP may cover the top surface of each of the outer electrode PO4, the gate dielectric layer GI, and the gate spacer GS.

A gate dielectric layer GI may be interposed between the gate electrode GE and the first channel pattern CH1 and between the gate electrode GE and the second channel pattern CH2. The gate dielectric layer GI may cover the top surface, the bottom surface, and the opposite sidewalls of each of the first, second, and third semiconductor patterns SP1, SP2, and SP3. The gate dielectric layer GI may cover a top surface of the device isolation layer ST below the gate electrode GE. The gate dielectric layer GI may cover the top surface of the third semiconductor pattern SP3 and lateral surfaces of the gate spacer GS.

In an example embodiment of the present inventive concepts, the gate dielectric layer GI may include one or more of a silicon oxide layer, a silicon oxynitride layer, and a high-k dielectric layer. For example, the gate dielectric layer GI may have a structure in which a silicon oxide layer and a high-k dielectric layer are stacked. The high-k dielectric layer may include a high-k dielectric material whose dielectric constant is greater than that of a silicon oxide layer. For example, the high-k dielectric material may include one or more of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In some example embodiments, a semiconductor device according to the present inventive concepts may include a negative capacitance field effect transistor that uses a negative capacitor. For example, the gate dielectric layer GI may include a ferroelectric material layer that exhibits ferroelectric properties and a paraelectric material layer that exhibits paraelectric properties.

The ferroelectric material layer may have a negative capacitance, and the paraelectric material layer may have a positive capacitance. For example, when two or more capacitors are connected in series, and when each capacitor has a positive capacitance, an overall capacitance may be reduced to be less than the capacitance of each capacitor. In contrast, when at least one of two or more capacitors connected in series has a negative capacitance, an overall capacitance may have a positive value that is increased to be greater than an absolute value of the capacitance of each capacitor.

When the ferroelectric material layer having a negative capacitance is connected in series to the paraelectric material layer having a positive capacitance, there may be an increase in overall capacitance of the ferroelectric and paraelectric material layers that are connected in series. The increase in overall capacitance may be used to allow a transistor including the ferroelectric material layer to have a sub-threshold swing of less than about 60 mV/decade at room temperature.

The ferroelectric material layer may have ferroelectric properties. The ferroelectric material layer may include, for example, one or more of hafnium oxide, hafnium zirconium oxide, barium strontium titanium oxide, and lead zirconium titanium oxide. For example, the hafnium zirconium oxide may be a material in which hafnium oxide is doped with zirconium (Zr). For another example, the hafnium zirconium oxide may be a compound of hafnium (Hf), zirconium (Zr), and oxygen (O).

The ferroelectric material layer may further include impurities doped therein. For example, the impurities may include at least one selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of impurities included in the ferroelectric material layer may be changed depending on what ferroelectric material is included in the ferroelectric material layer.

When the ferroelectric material layer includes hafnium oxide, the ferroelectric material layer may include at least one of impurities such as gadolinium (Gd), silicon (Si), zirconium (Zr), aluminum (Al), and yttrium (Y).

When the impurities are aluminum (Al), the ferroelectric material layer may include about 3 to 8 atomic percent aluminum. In this description, the ratio of impurities may be a ratio of aluminum to the sum of hafnium and aluminum.

When the impurities are silicon (Si), the ferroelectric material layer may include about 2 to about 10 atomic percent silicon. When the impurities are yttrium (Y), the ferroelectric material layer may include about 2 to about 10 atomic percent yttrium. When the impurities are gadolinium (Gd), the ferroelectric material layer may include about 1 to about 7 atomic percent gadolinium. When the impurities are zirconium (Zr), the ferroelectric material layer may include about 50 to about 80 atomic percent zirconium.

The paraelectric material layer may have paraelectric properties. The paraelectric material layer may include, for example, at least one selected from silicon oxide and high-k metal oxide. The metal oxide included in the paraelectric material layer may include, for example, one or more of hafnium oxide, zirconium oxide, and aluminum oxide, but the present inventive concepts are not limited thereto.

The ferroelectric and paraelectric material layers may include the same material. The ferroelectric material layer may have ferroelectric properties, but the paraelectric material layer may not have ferroelectric properties. For example, when the ferroelectric material layer and the paraelectric material layer include hafnium oxide, the hafnium oxide included in the ferroelectric material layer may have a crystal structure different from that of the hafnium oxide included in the paraelectric material layer.

The ferroelectric material layer may have a thickness having ferroelectric properties. The thickness of the ferroelectric material layer may range, for example, from about 0.5 nm to about 10 nm, but the present inventive concepts are not limited thereto. Because ferroelectric materials have their own critical thickness that exhibits ferroelectric properties, the thickness of the ferroelectric material layer may depend on ferroelectric material.

For example, the gate dielectric layer GI may include a single ferroelectric material layer. For another example, the gate dielectric layer GI may include a plurality of ferroelectric material layers that are spaced apart from each other. The gate dielectric layer GI may have a stack structure in which a plurality of ferroelectric material layers are alternately stacked with a plurality of paraelectric material layers.

Referring back to FIGS. 4 and 5A to 5D, the gate electrode GE may include a first metal pattern and a second metal pattern on the first metal pattern. The first metal pattern may be provided on the gate dielectric layer GI and may be adjacent to the first, second, and third semiconductor patterns SP1, SP2, and SP3. The first metal pattern may include a work-function metal that controls a threshold voltage of a transistor. A thickness and composition of the first metal pattern may be adjusted to achieve a desired threshold voltage of a transistor. For example, the first, second, and third inner electrodes PO1, PO2, and PO3 of the gate electrode GE may be formed of the first metal pattern or the work-function metal.

The first metal pattern may include a metal nitride layer. For example, the first metal pattern may include nitrogen (N) and at least one metal selected from titanium (Ti), tantalum (Ta), aluminum (Al), tungsten (W), and molybdenum (Mo). In addition, the first metal pattern may further include carbon @. The first metal pattern may include a plurality of stacked work-function metal layers.

The second metal pattern may include metal whose resistance is less than that of the first metal pattern. For example, the second metal pattern may include at least one metal selected from tungsten (W), aluminum (Al), titanium (Ti), and tantalum (Ta). For example, the outer electrode PO4 of the gate electrode GE may include a first metal pattern and a second metal pattern on the first metal pattern.

A gate structure GST may be defined by the outer electrode PO4 of the gate electrode GE, the gate spacer GS, and the gate dielectric layer GI interposed between the gate spacer GS and the outer electrode PO4. A horizontal distance in the second direction D2 of the gate structure GST may be the same as a horizontal distance in the second direction D2 of the capping pattern HMP. For example, a width in the second direction D2 of the gate structure GST may be the same as a width in the second direction D2 of the capping pattern HMP. With reference to FIGS. 6A to 6C, the following will describe in detail various examples of the gate structure GST and the capping pattern HMP according to the present inventive concepts.

A first interlayer dielectric layer 110 may be provided on the substrate 100. The first interlayer dielectric layer 110 may cover (e.g., surround) the gate spacers GS and the first and second source/drain patterns SD1 and SD2. The first interlayer dielectric layer 110 may have a top surface substantially coplanar with that of the gate spacer GS. The capping pattern HMP may be disposed on the first interlayer dielectric layer 110. A second interlayer dielectric layer 120 may be provided on the capping pattern HMP. A third interlayer dielectric layer 130 may be provided on the second interlayer dielectric layer 120. For example, the first, second, and third interlayer dielectric layers 110, 120, and 130 may include a silicon oxide layer.

The single height cell SHC may have a first boundary BD1 and a second boundary BD2 that are opposite to each other in the second direction D2. The first and second boundaries BD1 and BD2 may extend in the first direction D1. The single height cell SHC may have a third boundary BD3 and a fourth boundary BD4 that are opposite to each other in the first direction D1. The third and fourth boundaries BD3 and BD4 may extend in the second direction D2.

The single height cell SHC may be provided on its opposite sides with a pair of separation structures DB that are opposite to each other in the second direction D2. For example, the pair of separation structures DB may be provided on first and second boundaries BD1 and BD2 of the single height cell SHC, respectively. The separation structure DB may extend in the first direction D1 parallel to the gate electrodes GE. A pitch between the separation structure DB and its adjacent gate electrode GE may be the same as the first pitch.

The separation structure DB may penetrate the first interlayer dielectric layer 110 and the capping pattern HMP to extend into the first and second active patterns AP1 and AP2. The separation structure DB may penetrate an upper portion of each of the first and second active patterns AP1 and AP2. The separation structure DB may electrically separate an active region of the single height cell SHC from an active region of an adjacent another cell.

First and second active contacts AC1 and AC2 may be provided to penetrate the first interlayer dielectric layers 110 and the capping pattern HMP to come into electrical connection with the first and second source/drain patterns SD1 and SD2, respectively. A pair of active contacts AC1 and AC2 may be provided on opposite sides of the gate electrode GE. When viewed in plan, each of the first and second active contacts AC1 and AC2 may have a bar shape that extends in the first direction D1.

The first and second active contacts AC1 and AC2 may each be a self-aligned contact. For example, the capping pattern HMP and the gate spacer GS may be used to form the first and second active contacts AC1 and AC2 in a self-alignment manner. For example, the first and second active contacts AC1 and AC2 may each cover at least a portion of a sidewall of the gate spacer GS. Although not shown, the first and second active contacts AC1 and AC2 may cover a portion of the top surface of the capping pattern HMP.

The capping pattern HMP may be patterned in a fabrication method which will be discussed below, and the patterned capping pattern HMP in which seams and slits are not present may be used as a hard mask. Thus, metal fill failure that occurs when the first and second active contacts AC1 and AC2 are formed in a self-alignment manner may be reduced. It may thus be possible to reduce defects occurring when the first and second active contacts AC1 and AC2 are formed in a self-alignment manner and to increase reliability of a semiconductor device according to some example embodiments of the present inventive concepts.

The first active contact AC1 may vertically overlap the first source/drain pattern SD1. The first active contact AC1 may be electrically connected to the first source/drain pattern SD1. For example, the first active contact AC1 may have a lower portion that is inserted into the first source/drain pattern SD1, and the lower portion of the first active contact AC1 and the first source/drain pattern SD1 may be in contact with each other through a recess region.

The second active contact AC2 may vertically overlap the second source/drain pattern SD2. The second active contact AC2 may be electrically connected to the second source/drain pattern SD2. For example, the second active contact AC2 may have a lower portion that is inserted into the second source/drain pattern SD2, and the lower portion of the second active contact AC2 and the second source/drain pattern SD2 may be in contact with each other through a recess region.

A metal-semiconductor compound layer SC, such as a silicide layer, may be interposed between the first active contact AC1 and the first source/drain pattern SD1 and between the second active contact AC2 and the second source/drain pattern SD2. The metal-semiconductor compound layer SC may reduce a contact resistance between the first active contact AC1 and the first source/drain pattern SD1 and a contact resistance between the second active contact AC2 and the second source/drain pattern SD2. The first and second active contact AC1 and AC2 may be electrically connected through the metal-semiconductor compound layers SC to the first and second source/drain patterns SD1 and SD2. For example, the metal-semiconductor compound layer SC may include at least one selected from titanium silicide, tantalum silicide, tungsten silicide, nickel silicide, and cobalt silicide. The first active contact AC1 will be further discussed in detail below with reference to FIGS. 6A to 6C.

Gate contacts GC may be provided to penetrate the capping pattern HMP to come into electrical connection with corresponding gate electrodes GE. When viewed in plan, the gate contacts GC may be disposed to overlap the first active region AR1 and the second active region AR2, respectively. For example, the gate contact GC may be provided on the second active pattern AP2 (see FIG. 5B).

In an example embodiment of the present inventive concepts, referring to FIG. 5B, a space between the gate contact GC and an upper portion of the second active contact AC2 that is adjacent to the gate contact GC may be filled with an upper dielectric pattern UIP. The upper dielectric pattern UIP may have a bottom surface lower than that of the gate contact GC. For example, the upper dielectric pattern UIP may cause the second active contact AC2 adjacent to the gate contact GC to have a top surface lower than the bottom surface of the gate contact GC. Therefore, it may be possible to mitigate or prevent an electrical short caused by contact between the gate contact GC and its adjacent second active contact AC2.

The first active contact AC1 may include a first conductive pattern FM1 and a first barrier pattern BM1 that surrounds the first conductive pattern FM1, and the second active contact AC2 may include a second conductive pattern FM2 and a second barrier pattern BM2 that surrounds the second conductive pattern FM2. The gate contact GC may include a conductive pattern FM and a barrier pattern BM that surrounds the conductive pattern FM. For example, the conductive patterns FM1, FM2, and FM may each include at least one selected from aluminum, copper, tungsten, molybdenum, and cobalt. The barrier patterns BM1, BM2, and BM may cover sidewalls and bottom surfaces of the conductive patterns FM1, FM2, and FM, respectively. The barrier patterns BM1, BM2, and BM may each include a metal layer and a metal nitride layer. The metal layer may include at least one selected from titanium, tantalum, tungsten, nickel, cobalt, and platinum. The metal nitride layer may include at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PtN) layer.

A first metal layer M1 may be provided in the second interlayer dielectric layer 120. For example, the first metal layer M1 may include a first power line M1_R1, a second power line M1_R2, and first wiring lines M1_I. The lines M1_R1, M1_R2, and M1_I of the first metal layer M1 may extend in parallel to each other in the second direction D2.

For example, the first and second power lines M1_R1 and M1_R2 may be provided on the third and fourth boundaries BD3 and BD4 of the single height cell SHC, respectively. The first power line M1_R1 may extend in the second direction D2 along the third boundary BD3. The second power line M1_R2 may extend in the second direction D2 along the fourth boundary BD4.

The first wiring lines M1_I of the first metal layer M1 may be disposed between the first and second power lines M1_R1 and M1_R2. The first wiring lines M1_I of the first metal layer M1 may be arranged at a second pitch along the first direction D1. The second pitch may be less than the first pitch. Each of the first wiring lines M1_I may have a line-width less than that of each of the first and second power lines M1_R1 and M1_R2.

The first metal layer M1 may further include first vias VI1. The first vias VI1 may be provided below the lines M1_R1, M1_R2, and M1_I of the first metal layer M1, respectively. The first via VI1 may electrically connect the active contact AC to one of the lines M1_R1, M1_R2, M1_R3, and M1_I of the first metal layer M1. The first via VI1 may electrically connect the gate contact GC to one of the lines M1_R1, M1_R2, and M1_I of the first metal layer M1.

A certain line and its underlying first via VI1 of the first metal layer M1 may be formed by individual processes. For example, the certain line and its underlying first via VI1 of the first metal layer M1 may each be formed by a single damascene process. A sub-20 nm process may be employed to fabricate a semiconductor device according to some example embodiments.

A second metal layer M2 may be provided in the third interlayer dielectric layer 130. The second metal layer M2 may include a plurality of second wiring lines M2_I. The second wiring lines M2_I of the second metal layer M2 may each have a linear or bar shape that extends in the first direction D1. For example, the second wiring lines M2_I may extend in parallel to each other in the first direction D1.

The second metal layer M2 may further include second vias VI2 that are provided below the second wiring lines M2_I, respectively. A certain line of the first metal layer M1 may be electrically connected through the second via VI2 to a corresponding line of the second metal layer M2. For example, a wiring line and its underlying second via VI2 of the second metal layer M2 may be simultaneously formed in a dual damascene process.

The first and second metal layers M1 and M2 may have their wiring lines that include the same or different conductive materials. For example, the wiring lines of the first and second metal layers M1 and M2 may include at least one metallic material selected from aluminum, copper, tungsten, molybdenum, ruthenium, and cobalt. Although not shown, other metal layers (e.g., M3, M4, M5, etc.) may be additionally stacked on the third interlayer dielectric layer 130. Each of the stacked metal layers may include wiring lines for routing between cells.

With reference to FIGS. 6A to 6C, the following will describe in detail the gate structure GST, the capping pattern HMP, and the first and second active contacts AC1 and AC2. The gate structure GST may include the outer electrode PO4 of the gate electrode GE, a pair of gate spacers GS, and the gate dielectric layer GI interposed between the gate spacers GS and the outer electrode PO4. The capping pattern HMP may be provided on the gate structure GST. A horizontal distance in the second direction D2 of the gate structure GST may be different from a horizontal distance in the second direction D2 of the capping pattern HMP. For example, a width in the second direction D2 of the gate structure GST may be different from a width in the second direction D2 of the capping pattern HMP.

A line-width of the gate structure GST may be defined as a second width GSTW. For example, the second width GSTW may be defined to indicate a length in the second direction D2 of the gate structure GST. The second width GSTW may be a horizontal distance between lateral surfaces of the gate spacer GS that are in contact with the first interlayer dielectric layer 110.

Referring to FIG. 6A, a line-width of the capping pattern HMP may be defined as a third width MPW1. For example, the third width MPW1 may be defined to indicate a length in the second direction D2 of the capping pattern HMP. The third width MPW1 may be a horizontal distance between lateral surfaces of the capping pattern HMP in contact with the first active contact AC1. The third width MPW1 may be greater than the second width GSTW.

For example, a top surface of the capping pattern HMP may be coplanar with that of the first active contact AC1. A bottom surface of the capping pattern HMP may cover the top surface of the gate structure GST and a portion of the top surface of the first interlayer dielectric layer 110 adjacent to the gate structure GST. As the third width MPW1 of the capping pattern HMP is greater than the second width GSTW of the gate structure GST, the first active contact AC1 formed in a self-alignment manner may have a reduced width in the second direction D2.

The width in the second direction D2 of the first active contact AC1 may be less than a width in the second direction D2 of the first source/drain pattern SD1. For example, a maximum width in the second direction D2 of the first active contact AC1 may be less than a maximum width in the second direction D2 of the first source/drain pattern SD1.

Referring to FIG. 6B, a line-width of the capping pattern HMP may be defined as a fourth width MPW2. For example, the fourth width MPW2 may be defined to indicate a length in the second direction D2 of the capping pattern HMP. The fourth width MPW2 may be a horizontal distance between lateral surfaces of the capping pattern HMP in contact with the first active contact AC1. The fourth width MPW2 may be less than the second width GSTW.

For example, a top surface of the capping pattern HMP may be coplanar with that of the first active contact AC1. A bottom surface of the capping pattern HMP may cover a portion of the top surface of the gate structure GST. For example, the bottom surface of the capping pattern HMP may be in contact with a top surface of the outer electrode PO4 and a top surface of the gate dielectric layer GI. As the fourth width MPW2 of the capping pattern HMP is less than the second width GSTW of the gate structure GST, the first active contact AC1 formed in a self-alignment manner may have an increased width in the second direction D2.

The first active contact AC1 may include a body part BP and a protrusion part EP that expands from the body part BP to the first source/drain pattern SD1. The body part BP may be interposed between neighboring capping patterns HMP. The body part BP may extend from on the first source/drain pattern SD1 onto the top surface of the gate spacer GS.

A width in the second direction D2 of the first active pattern AP1 may be greater than a width in the second direction D2 of the first source/drain pattern SD1. For example, a maximum width in the second direction D2 of the first active contact AC1 may be greater than a maximum width in the second direction D2 of the first source/drain pattern SD1. The maximum width of the first active contact AC1 may be a width in the second direction D2 of the body part BP.

Referring to FIG. 6C, a line-width of the capping pattern HMP may be defined as a fifth width MPW3. For example, the fifth width MPW3 may be defined to indicate a length in the second direction D2 of the capping pattern HMP. The fifth width MPW3 may be a horizontal distance between lateral surfaces of the capping pattern HMP in contact with the first active contact AC1. The fifth width MPW3 may be the same as the second width GSTW. In an example embodiment, the fifth width MPW3 may be different from the second width GSTW.

As shown in FIG. 6C, although the fifth width MPW3 of the capping pattern HMP is the same as the second width GSTW of the gate structure GST, the capping pattern HMP and the gate structure GST may be misaligned with each other. For example, the gate structure GST may have a first center line C_GST, and the capping pattern HMP may have a second center line C_HMP. The first center line C_GST and the second center line C_HMP may be offset from each other.

A top surface of the active contacts AC may be coplanar with that of the first active contact AC1. A bottom surface of the capping pattern HMP may cover a portion of the top surface of the first interlayer dielectric layer 110 and a portion of the top surface of the gate structure GST. A bottom surface of the capping pattern HMP may in contact with the top surface of outer electrode PO4, the top surface of the gate dielectric layer GI, the top surface of one of a pair of gate spacers GS, and a portion of the top surface of the first interlayer dielectric layer 110.

The first active contact AC1 may include a body part BP and a protrusion part EP that expands from the body part BP to the first source/drain pattern SD1. The body part BP may be interposed between neighboring capping patterns HMP. The body part BP may extend from on the first source/drain pattern SD1 onto the top surface of the gate spacer GS. For example, the body part BP may be in contact with the top surface of the gate spacer GS. A width in the second direction D2 of the body part BP may be greater than a width in the second direction D2 of the protrusion part EP. This may be caused by the fact that the capping pattern HMP and the gate structure GST are misaligned with each other.

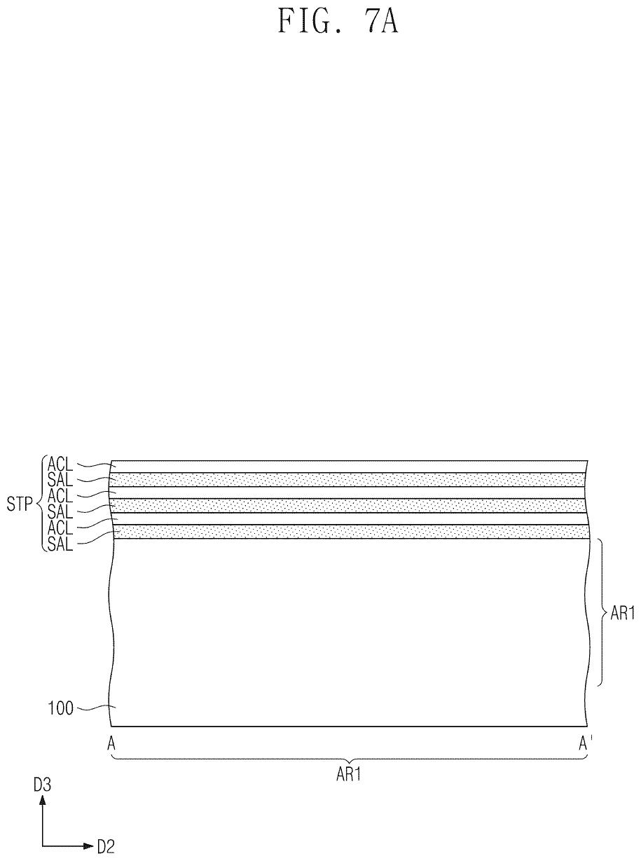

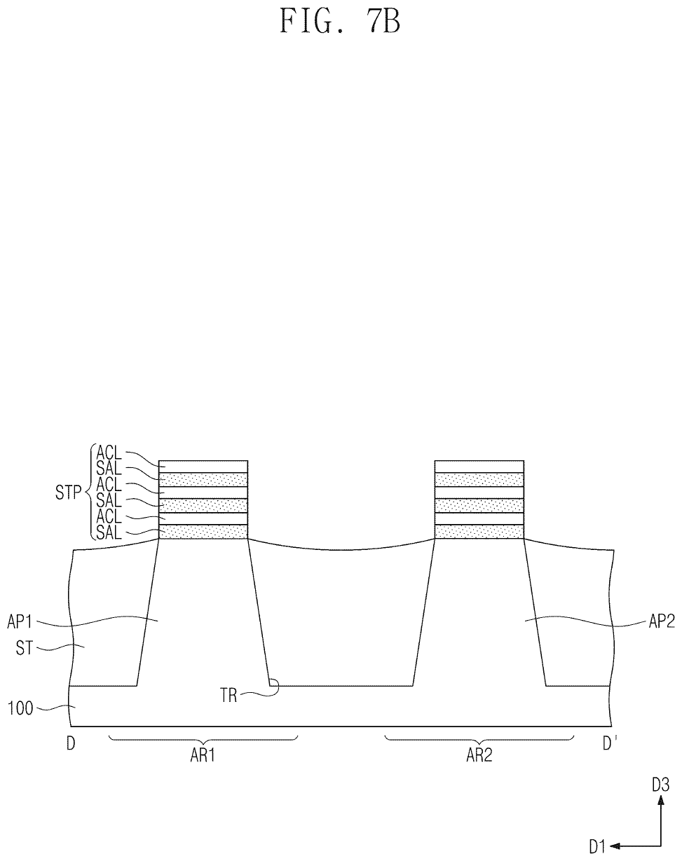

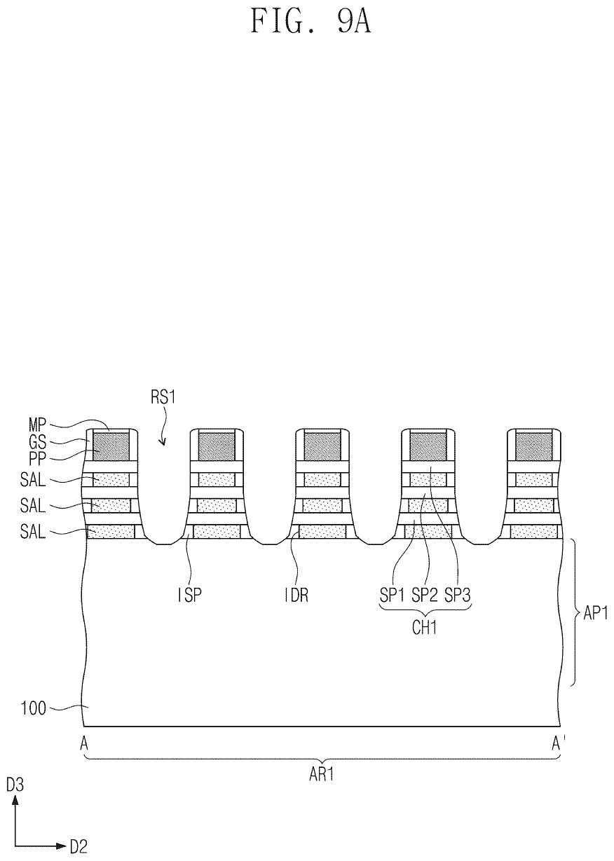

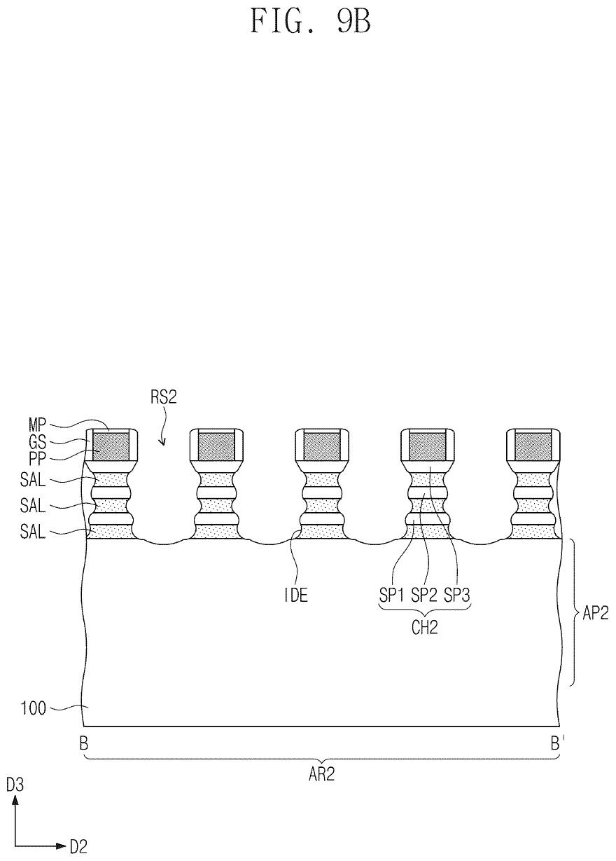

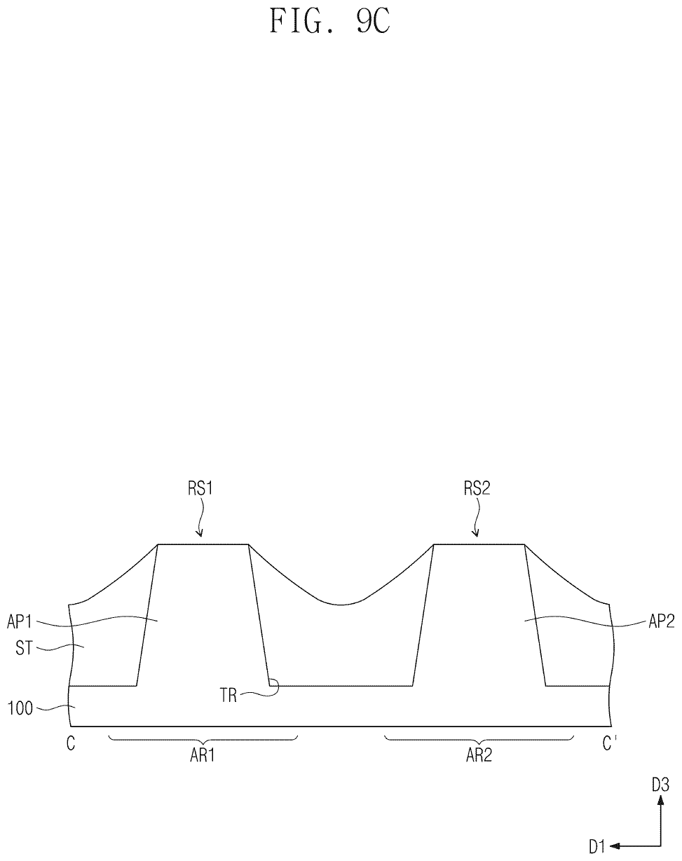

FIGS. 7A to 14C illustrate cross-sectional views showing a method of fabricating a semiconductor device according to an example embodiment of the present inventive concepts. In detail, FIGS. 7A, 8A, 9A, 10A, 11A, 12A, 13A, and 14A illustrate cross-sectional views taken along line A-A′ of FIG. 4. FIGS. 9B, 10B, 11B, 12B, 13B, and 14B illustrate cross-sectional views taken along line B-B′ of FIG. 4. FIGS. 9C, 10C, 11C, 13C, and 14C illustrate cross-sectional views taken along line C-C′ of FIG. 4. FIGS. 7B, 8B, 11D, 12C, and 13D illustrate cross-sectional views taken along line D-D′ of FIG. 4.

Referring to FIGS. 7A and 7B, a substrate 100 may be provided which includes a first active region AR1 and a second active region AR2. Active layers ACL and sacrificial layers SAL may be alternately formed on the substrate 100. The active layers ACL may include one of silicon (Si), germanium (Ge), and silicon-germanium (SiGe), and the sacrificial layers SAL may include another of silicon (Si), germanium (Ge), and silicon-germanium (SiGe).

The sacrificial layer SAL may include a material having an etch selectivity with respect to the active layer ACL. For example, the active layers ACL may include silicon (Si), and the sacrificial layers SAL may include silicon-germanium (SiGe). Each of the sacrificial layers SAL may have a germanium concentration of about 10 at % to about 30 at %.

Mask patterns may be formed on each of the first and second active regions AR1 and AR2 of the substrate 100. The mask pattern may have a linear or bar shape that extends in a second direction D2.

A patterning process may be performed in which the mask patterns are used as an etching mask to form a trench TR that defines a first active pattern AP1 and a second active pattern AP2. The first active pattern AP1 may be formed on the first active region AR1. The second active pattern AP2 may be formed on the second active region AR2.

A stack pattern STP may be formed on each of the first and second active patterns AP1 and AP2. The stack pattern STP may include the active layers ACL and the sacrificial layers SAL that are alternately stacked. During the patterning process, the stack pattern STP may be formed together with the first and second active patterns AP1 and AP2.

A device isolation layer ST may be formed to fill the trench TR. For example, a dielectric layer may be formed on an entire surface of the substrate 100 to cover the stack patterns STP and the first and second active patterns AP1 and AP2. The dielectric layer may be recessed until the stack patterns STP are exposed, and thus the device isolation layer ST may be formed.

The device isolation layer ST may include a dielectric material, such as a silicon oxide layer. The stack patterns STP may be exposed upwardly from the device isolation layer ST. For example, the stack patterns STP may vertically protrude upwards from the device isolation layer ST.

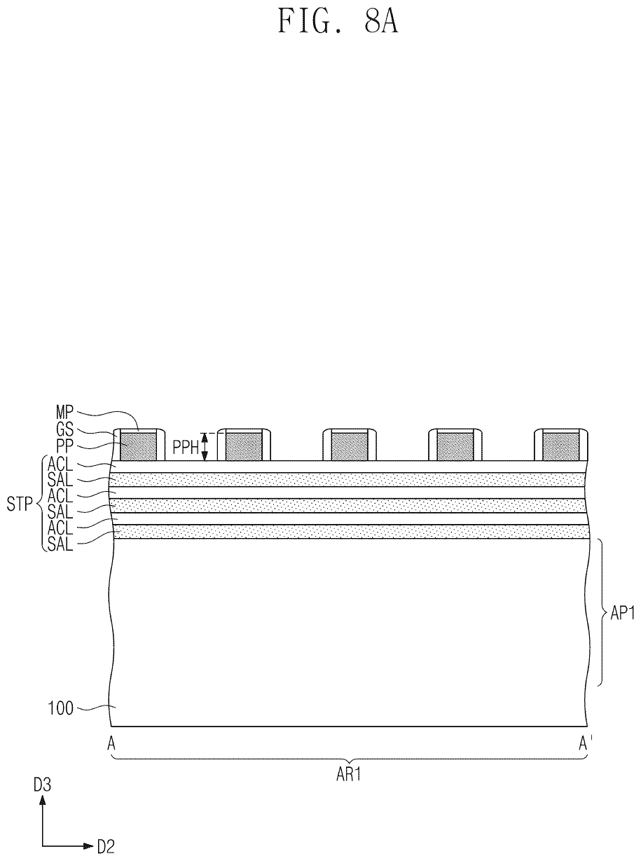

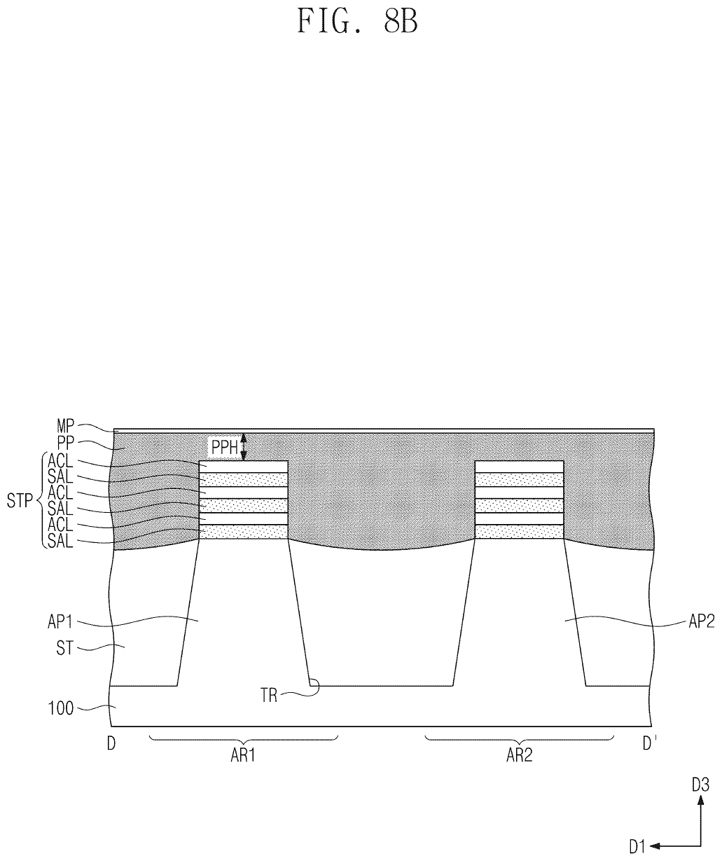

Referring to FIGS. 8A and 8B, sacrificial patterns PP may be formed on the substrate 100, running across the stack patterns STP. Each of the sacrificial patterns PP may be formed to have a linear or bar shape that extends in a first direction D1. The sacrificial patterns PP may be arranged at a first pitch along the second direction D2.

For example, the formation of the sacrificial patterns PP may include forming a sacrificial layer on the entire surface of the substrate 100, forming hardmask patterns MP on the sacrificial layer, and using the hardmask patterns MP as an etching mask to pattern the sacrificial layer. The sacrificial layer may include polysilicon.

The formation of the sacrificial layer on the entire surface of the substrate 100 may include depositing the sacrificial layer to a certain thickness. The certain thickness may be a first thickness PPH of each of the sacrificial patterns PP formed by patterning the sacrificial layer. The first thickness PPH may be defined to indicate a height of each of the sacrificial patterns PP on the stack patterns STP. For example, the first thickness PPH may correspond to the first height (see GEH of FIG. 5A) of the outer electrode (see PO4 of FIG. 5A) discussed above. The first thickness PPH may be a vertical distance from a top surface of an uppermost sacrificial layer ACL to an uppermost surface of the sacrificial pattern PP. For example, the first thickness PPH may range from about 5.0 nm to about 30.0 nm, for example, from about 10.0 nm to about 12.0 nm.

As the sacrificial layer is formed to have a small height (e.g., the first thickness PPH), the sacrificial pattern PP may improve in profile failure. For example, the sacrificial pattern PP may mitigate or prevent wiggling and tailing (or skirt phenomenon) that is produced at a lower portion thereof. In addition, as the sacrificial pattern PP has a reduced height, it may be possible to suppress an un-etch issue of source/drain patterns and an un-strip phenomenon of polysilicon in a subsequent process. Therefore, reliability of a semiconductor device may increase and profile failures caused by a large height of the sacrificial pattern PP may decrease.

A pair of gate spacers GS may be formed on opposite sidewalls of each of the sacrificial patterns PP. The formation of the gate spacers GS may include conformally forming a gate spacer layer on the entire surface of the substrate 100 and anisotropically etching the gate spacer layer. In an example embodiment of the present inventive concepts, the gate spacer GS may be a multiple layer including at least two layers.

Referring to FIGS. 9A to 9C, first recesses RS1 may be formed in the stack pattern STP on the first active pattern AP1. Second recesses RS2 may be formed in the stack pattern STP on the second active pattern AP2. During the formation of the first and second recesses RS1 and RS2, the device isolation layer ST may further be recessed on opposite sides of each of the first and second active patterns AP1 and AP2 (see FIG. 9C).

For example, the hardmask patterns MP and the gate spacers GS may be used as an etching mask to etch the stack pattern STP on the first active pattern AP1 to form the first recesses RS1. The first recess RS1 may be formed between a pair of sacrificial patterns PP.

The active layers ACL may be formed into first, second, and third semiconductor patterns SP1, SP2, and SP3 that are sequentially stacked between neighboring first recesses RS1. A first channel pattern CH1 may be constituted by the first, second, and third semiconductor patterns SP1, SP2, and SP3 between neighboring first recesses RS1.

The first recess RS1 may be formed between neighboring sacrificial patterns PP. A width in the second direction D2 of the first recess RS1 may decrease with decreasing distance from the substrate 100.

The first recess RS1 may expose the sacrificial layers SAL. A selective etching process may be performed on the exposed sacrificial layers SAL. The etching process may include a wet etching process that selectively etches silicon-germanium. In the etching process, each of the sacrificial layers SAL may be indented to form an indent region IDR. The indent region IDR may allow the sacrificial layer SAL to have a concave sidewall. A dielectric layer may be formed in the first recess RS1, filling the indent regions IDR. The sacrificial layers SAL and the first, second, and third semiconductor patterns SP1, SP2, and SP3 exposed by the first recess RS1 may become a seed layer for the dielectric layer. The dielectric layer grow as a crystalline dielectric layer on a crystalline semiconductor included in the sacrificial layers SAL and the first, second, and third semiconductor patterns SP1, SP2, and SP3.

An inner spacer ISP may be formed to fill the indent region IDR. For example, the formation of the inner spacer ISP may include wet-etching an epitaxial dielectric layer until sidewalls of the first, second, and third semiconductor patterns SP1, SP2, and SP3 are exposed. Therefore, the epitaxial dielectric layer may remain only in the indent region IDR, thereby constituting the inner spacer ISP.

Referring back to FIGS. 9A to 9C, the second recesses RS2 in the stack pattern STP on the second active pattern AP2 may be formed by a method similar to that used for forming the first recesses RS1. The sacrificial layers SAL exposed by the second recess RS2 may undergo a selective etching process to form the indent regions IDE on the second active pattern AP2. The indent regions IDE may cause the second recess RS2 to have a wave-shape inner sidewall. The inner spacers ISP may not be formed in the indent regions IDE on the second active pattern AP2. A second channel pattern CH2 may be constituted by the first, second, and third semiconductor patterns SP1, SP2, and SP3 between neighboring second recesses RS2.

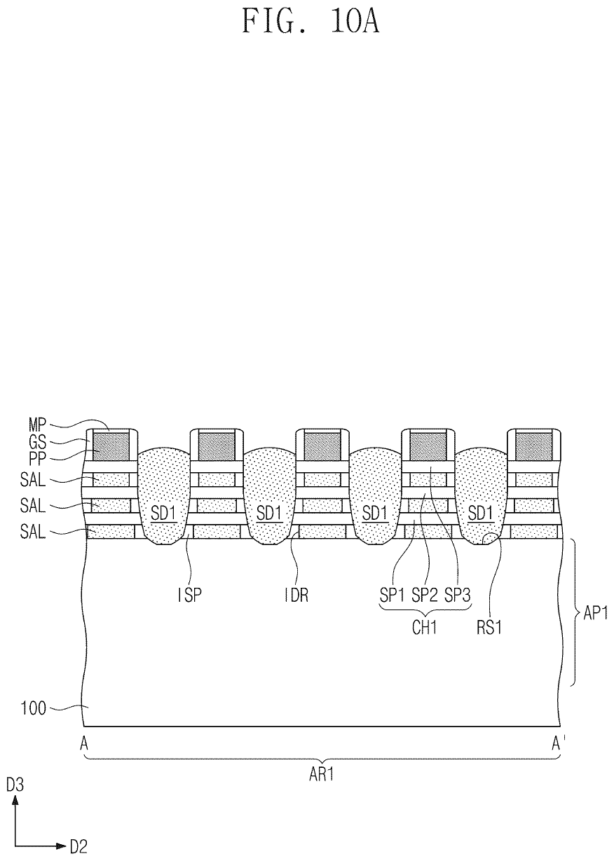

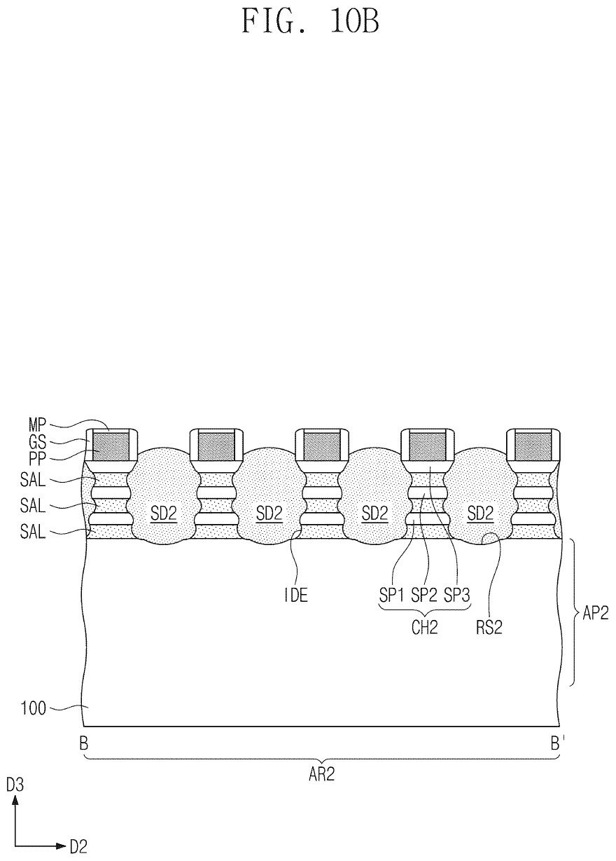

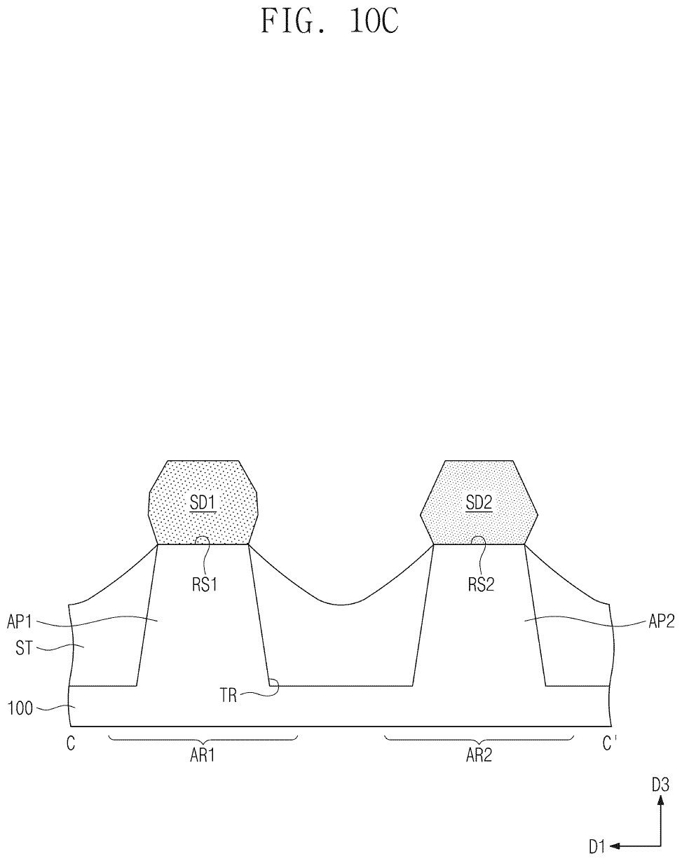

Referring to FIGS. 10A to 10C, first source/drain patterns SD1 may be formed in the first recesses RS1, respectively. For example, a selective epitaxial growth (SEG) process may be performed in which an inner sidewall of the first recess RS1 is used as a seed layer to form an epitaxial layer that fills the first recess RS1. The epitaxial layer may be grown from a seed or the substrate 100 and the first, second, and third semiconductor patterns SP1, SP1, and SP3 exposed by the first recess RS1. For example, the SEG process may include chemical vapor deposition (CVD) or molecular beam epitaxy (MBE).

In an example embodiment of the present inventive concepts, the first source/drain pattern SD1 may include the same semiconductor element (e.g., Si) as that of the substrate 100. While the first source/drain pattern SD1 is formed, impurities (e.g., phosphorus, arsenic, or antimony) may be in-situ implanted to allow the first source/drain pattern SD1 to have n-type conductivity. In some example embodiments, after the formation of the first source/drain pattern SD1, impurities may be implanted into the first source/drain pattern SD1.

Second source/drain patterns SD2 may be formed in the second recesses RS2, respectively. For example, a selective epitaxial growth (SEG) process may be performed such that an inner sidewall of the second recess RS2 is used as a seed to form the second source/drain pattern SD2.

In an example embodiment of the present inventive concepts, the second source/drain pattern SD2 may include a semiconductor element (e.g., SiGe) whose lattice constant is greater than that of a semiconductor element of the substrate 100. While the second source/drain pattern SD2 is formed, impurities (e.g., boron, gallium, or indium) may be in-situ implanted to allow the second source/drain pattern SD2 to have p-type conductivity. In some example embodiments, after the formation of the second source/drain pattern SD2, impurities may be implanted into the second source/drain pattern SD2.

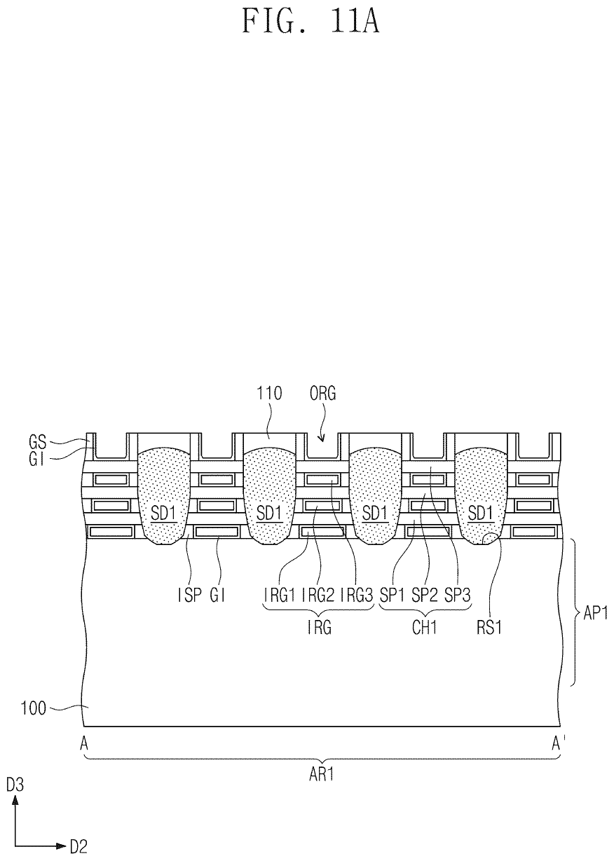

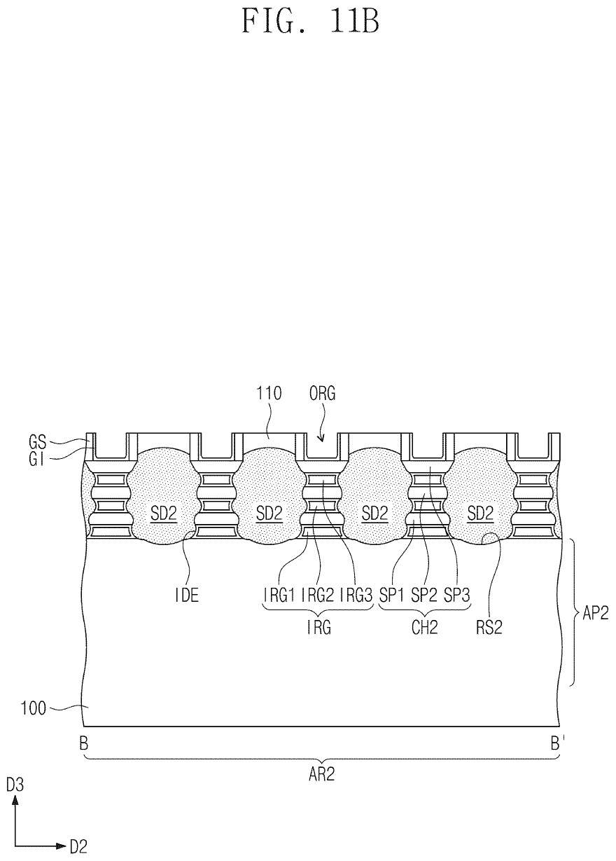

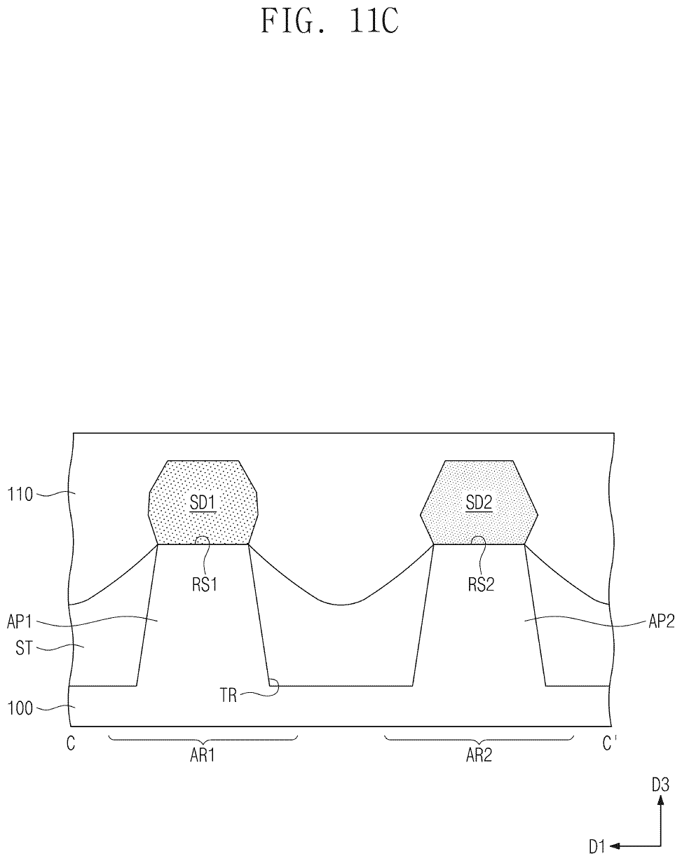

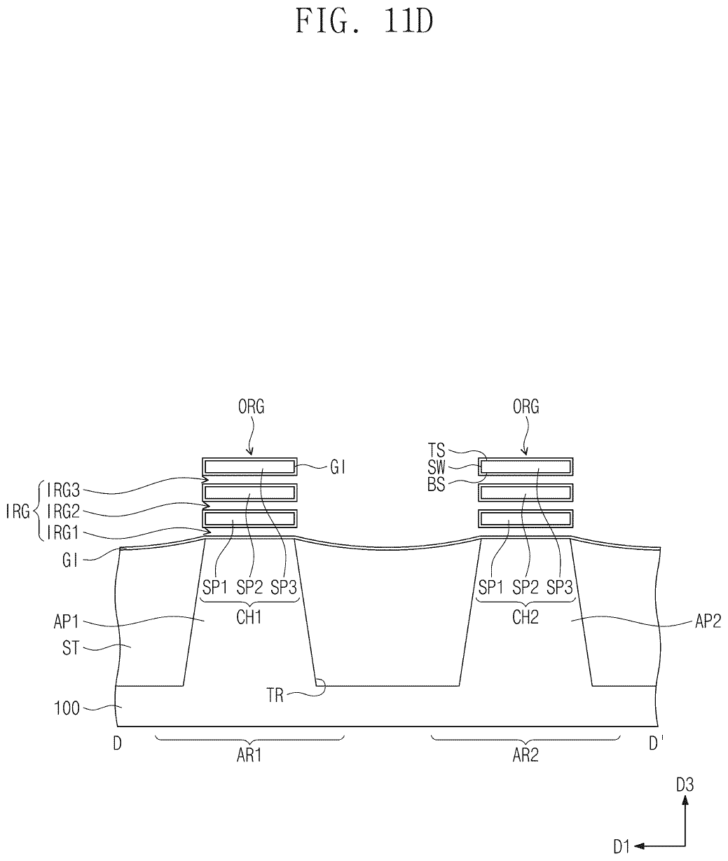

Referring to FIGS. 11A to 11D, a first interlayer dielectric layer 110 may be formed to cover the first and second source/drain patterns SD1 and SD2, the hardmask patterns MP, and the gate spacers GS. For example, the first interlayer dielectric layer 110 may include a silicon oxide layer.

The first interlayer dielectric layer 110 may be planarized until top surfaces of the sacrificial patterns PP are exposed. An etch-back or chemical mechanical polishing (CMP) process may be employed to planarize the first interlayer dielectric layer 110. The hardmask patterns MP may all be removed during the planarization process. Thus, the first interlayer dielectric layer 110 may have a top surface coplanar with those of the sacrificial patterns PP and those of the gate spacers GS.

The exposed sacrificial patterns PP may be selectively removed. The removal of the sacrificial patterns PP may form an outer region ORG that exposes the first and second channel patterns CH1 and CH2 (see FIG. 11D). The removal of the sacrificial patterns PP may include performing a wet etching process using an etchant that selectively etches polysilicon.

The sacrificial layers SAL exposed through the outer region ORG may be selectively removed to form inner regions IRG (see FIG. 11D). For example, an etching process that selectively etches the sacrificial layers SAL may be performed such that only the sacrificial layers SAL may be removed while leaving the first, second, and third semiconductor patterns SP1, SP2, and SP3. The etching process may have a high etch rate with respect to silicon-germanium having a relatively high germanium concentration. For example, the etching process may have a high etch rate with respect to silicon-germanium whose germanium concentration is greater than about 10 at %.

The etching process may remove the sacrificial layers SAL on the first and second active regions AR1 and AR2. The etching process may be a wet etching process. An etching material used for the etching process may promptly etch the sacrificial layer SAL whose germanium concentrate is relatively high.

Referring back to FIG. 11D, as the sacrificial layers SAL are selectively removed, the stacked first, second, and third semiconductor patterns SP1, SP2, and SP3 may remain on each of the first and second active patterns AP1 and AP2. The removal of the sacrificial layers SAL may form first, second, and third inner regions IRG1, IRG3, and IRG3.

For example, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

Referring back to FIGS. 11A to 11D, a gate dielectric layer GI may be formed on the exposed first, second, and third semiconductor patterns SP1, SP2, and SP3. The gate dielectric layer GI may be formed to surround each of the first, second, and third semiconductor patterns SP1, SP2, and SP3. The gate dielectric layer GI may be formed in each of the first, second, and third inner regions IRG1, IRG2, and IRG3. The gate dielectric layer GI may be formed in the outer region ORG.

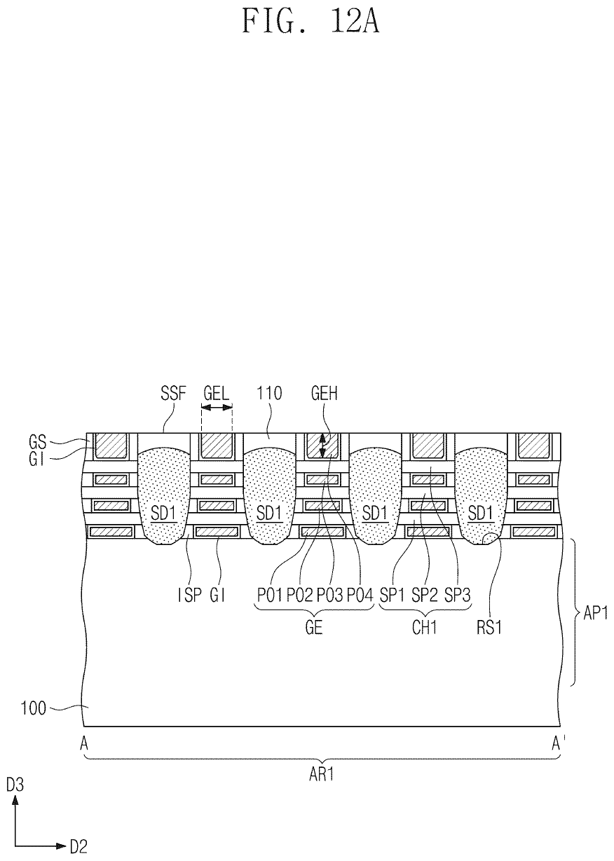

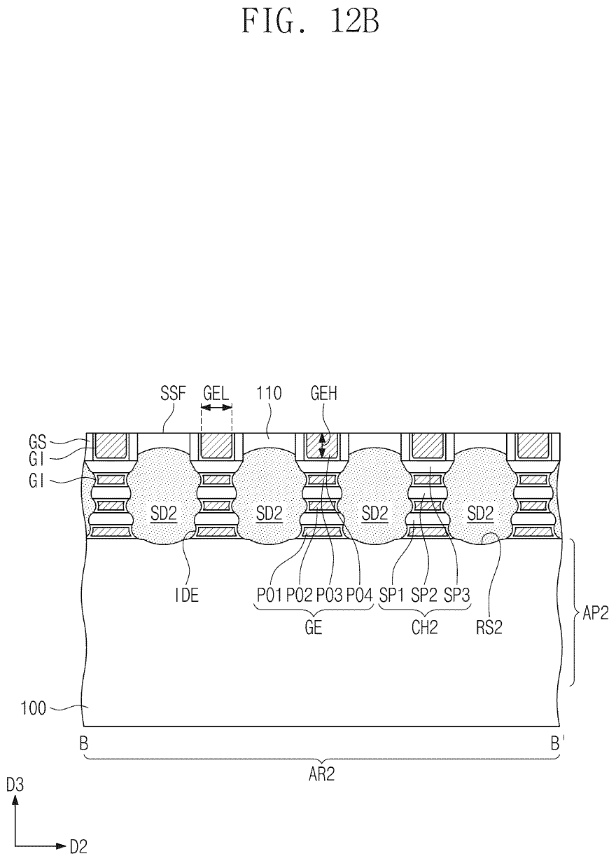

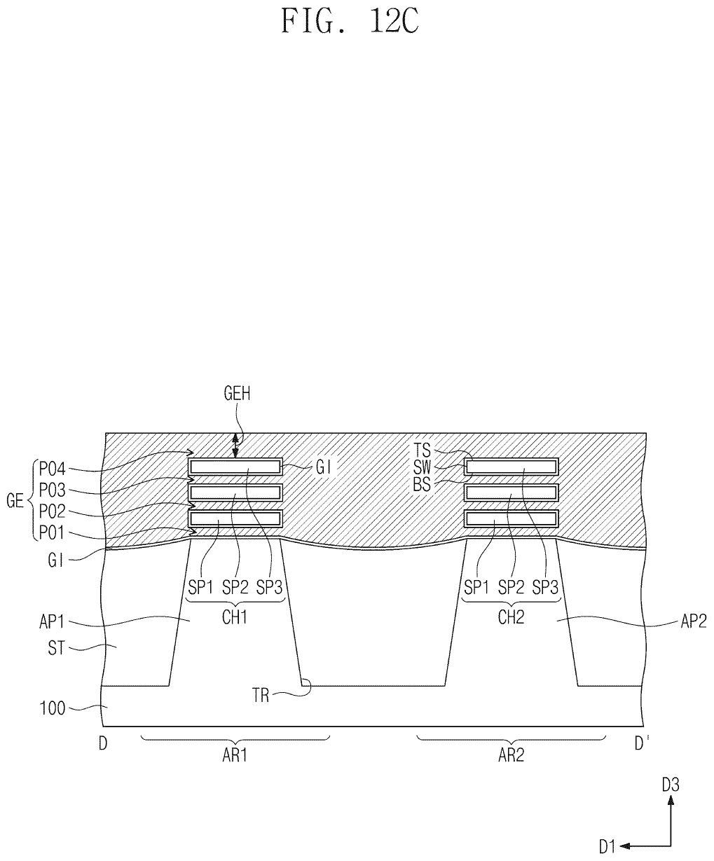

Referring to FIGS. 12A to 12C, a gate electrode GE may be formed on the gate dielectric layer GI. The gate electrode GE may include first, second, and third inner electrodes PO1, PO2, and PO3 that are respectively formed in the first, second, and third inner regions IRG1, IRG2, and IRG3, and may also include an outer electrode PO4 formed in the outer region ORG.

For example, the formation of the gate electrode GE may include forming a first metal layer in the first, second, and third inner regions IRG1, IRG2, and IRG3 and the outer region ORG, forming a second metal layer on the first metal layer, and using a top surface SSF of the first interlayer dielectric layer 110 as a stopper to perform a chemical mechanical polishing (CMP) process on the first and second metal layers. The first metal layer may include a metal nitride layer, and the second metal layer may include metal whose resistance is low.

The formation of the first metal layer and the second metal layer may include depositing the first and second metal layers to cover the gate dielectric layer GI, the top surface SSF of the first interlayer dielectric layer 110, and the top surface of the gate spacer GS. The performing the CMP process on the first and second metal layers may include using slurry to remove the first and second metal layers. The CMP process may stop at the top surface SSF (serving as a stopper) of the first interlayer dielectric layer 110 including silicon oxide. The CMP process may be performed such that the top surface SSF of the first interlayer dielectric layer 110 may be substantially coplanar with that of the outer electrode PO4, that of the gate dielectric layer GI, and that of the gate spacer GS.

The outer electrode PO4 of the gate electrode GE may have a line-width in the second direction D2 and a height in the third direction D3. The line-width may be defined as a first width GEL, and the height may be defined as a first height GEH. After the CMP process is performed on the first and second metal layers, the first height GEH may range from about 5.0 nm to about 30.0 nm. The first width GEL may range from about 5.0 nm to about 30.0 nm. The CMP process may be performed such that the first height GEH of the outer electrode PO4 may be equal to or less than the first width GEL.

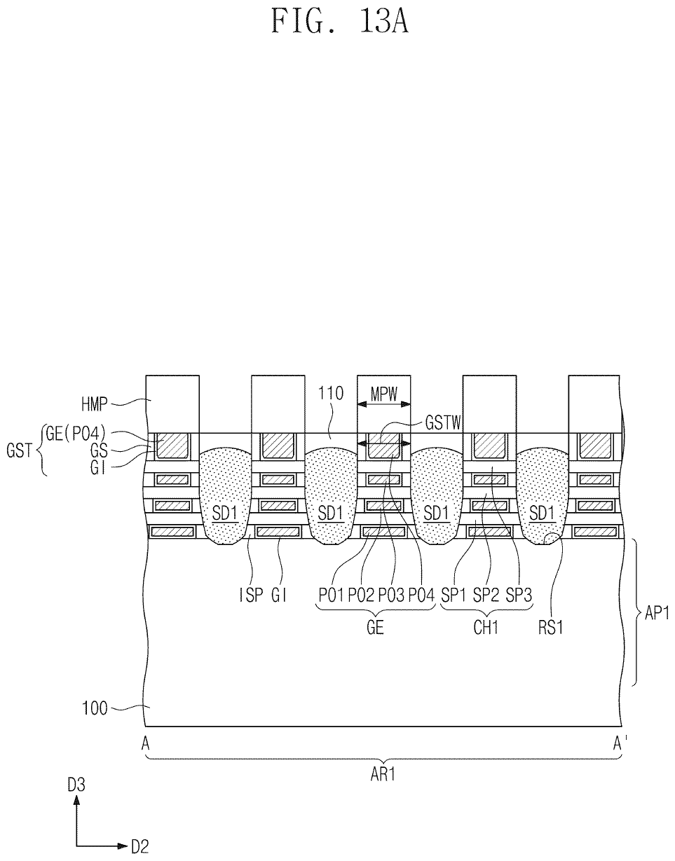

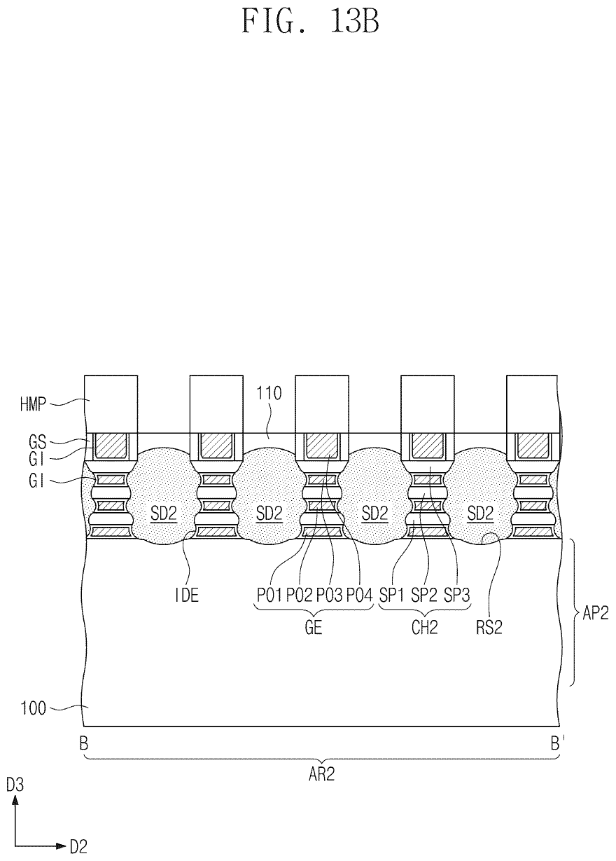

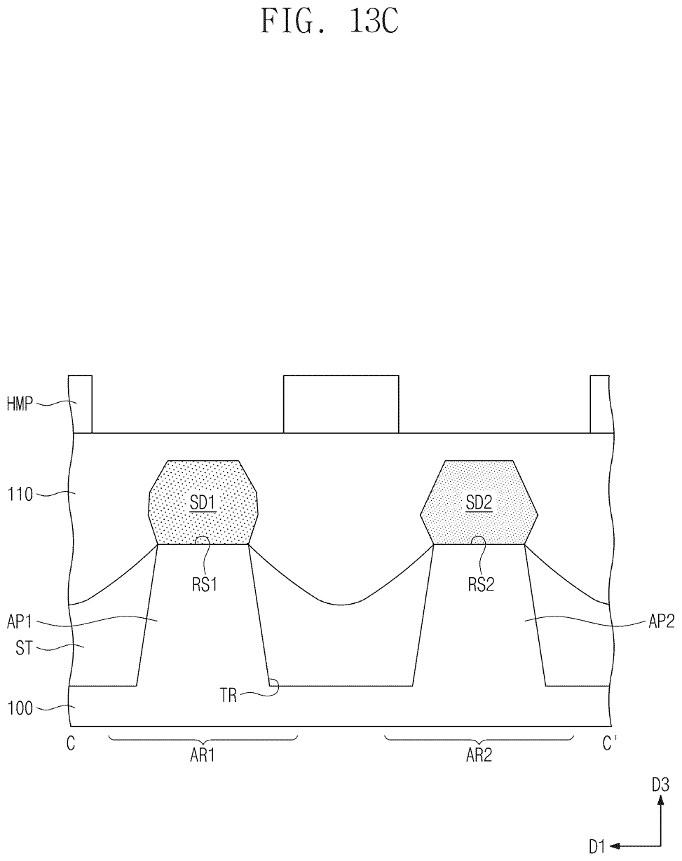

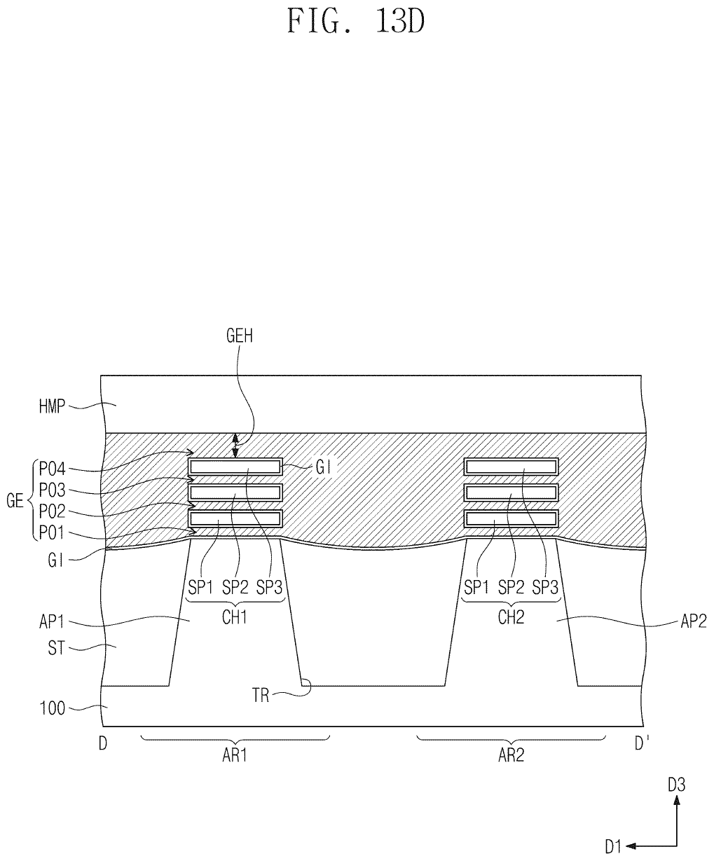

Referring to FIGS. 13A to 13D, a capping pattern HMP may be formed on the outer electrode PO4, the gate dielectric layer GI, and the gate spacer GS. The capping pattern HMP may include at least one selected from SiN, SiOC, SiOCN, SiCN, SiCON, TIN, WC, and a combination thereof. The capping pattern HMP may expose the first interlayer dielectric layer 110.

For example, the formation of the capping pattern HMP may include forming a capping layer on the first interlayer dielectric layer 110, the outer electrode PO4, the gate dielectric layer GI, and the gate spacer GS, forming mask patterns on the capping layer, and using the mask patterns as an etching mask to pattern the capping layer. The capping layer may include a material having an etch selectivity with respect to silicon oxide.

The formation of the capping layer on the first interlayer dielectric layer 110, the outer electrode PO4, the gate dielectric layer GI, and the gate spacer GS may include deposition of the capping layer on an entirety of the substrate 100. The capping layer may be uniformly deposited as a whole, and thus it may be possible to improve failure caused by pattern density or the like. For example, the capping layer may not include any of seams and slits. Therefore, process failure may be reduced in forming active contacts in a subsequent process. Thus a semiconductor devices according to some example embodiments of the present inventive concepts may increase in reliability.

A gate structure GST may be defined which includes the outer electrode PO4 of the gate electrode GE, the gate spacer GS, and the gate dielectric layer GI interposed between the gate spacer GS and the outer electrode PO4. The gate structure GST may have a horizontal distance in the second direction D2. The horizontal distance may correspond to a line-width of the gate structure GST, and the line-width may be defined as a second width GSTW. For example, the second width GSTW may be a length in the second direction D2 of the gate structure GST.

The capping pattern HMP on the gate structure GST may have a horizontal distance in the second direction D2. The horizontal distance may correspond to a line-width of the capping pattern HMP, and the line-width may be defined as a width MPW of the capping pattern HMP. For example, the width MPW of the capping pattern HMP may be a length in the second direction D2 of the capping pattern HMP. The width MPW of the capping pattern HMP may have various values as discussed in FIGS. 6A to 6C.

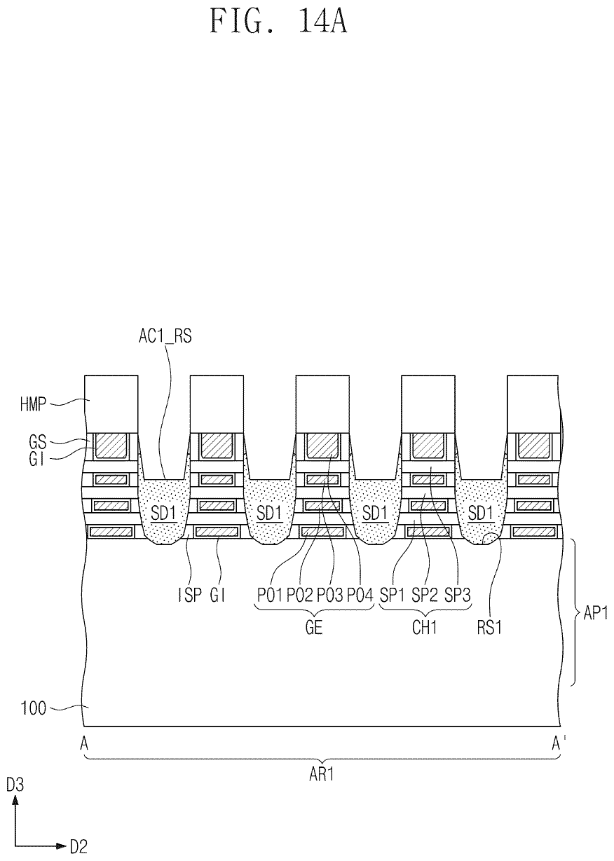

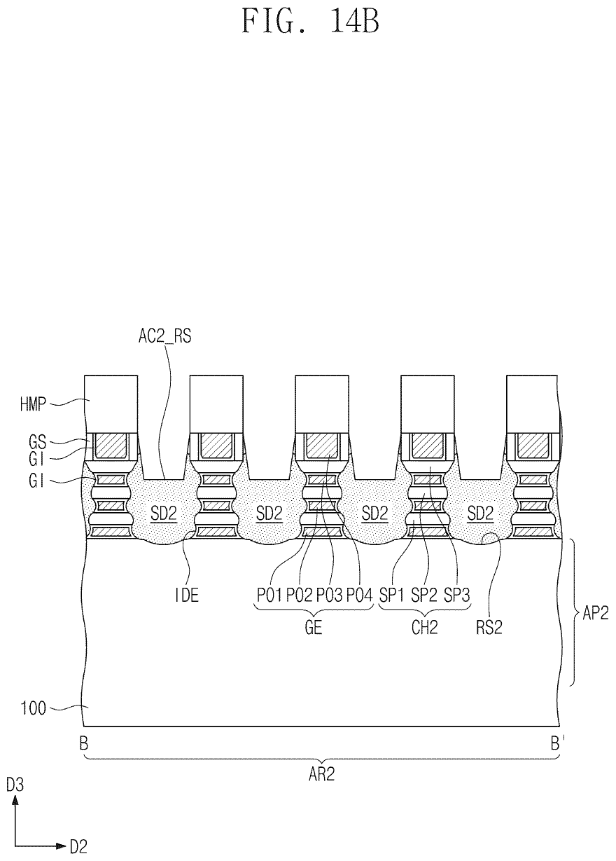

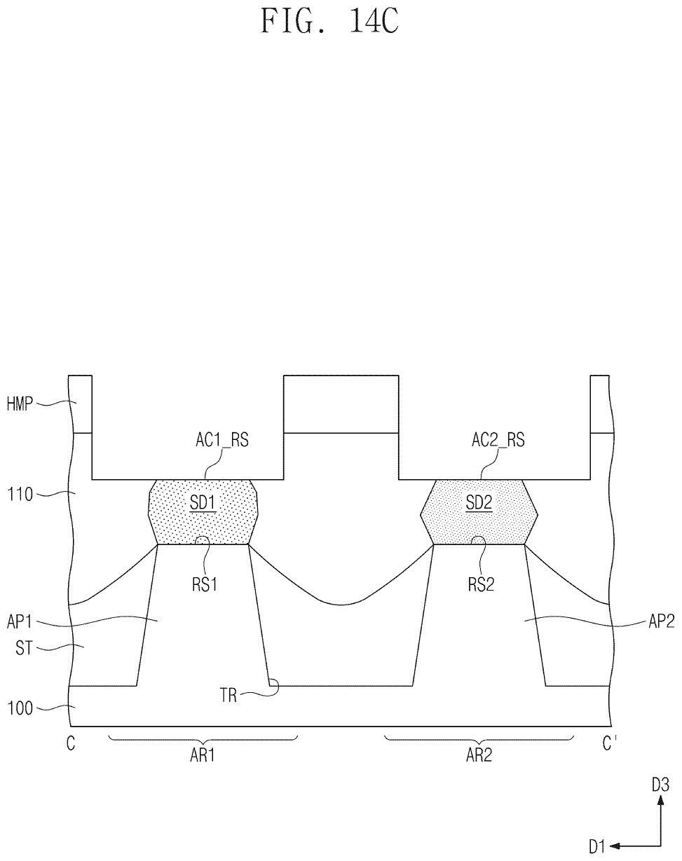

Referring to FIGS. 14A to 14C, the capping pattern HMP may be used as an etching mask to form first and second recess regions AC1_RS and AC2_RS that penetrate the first interlayer dielectric layer 110. The first and second recess regions AC1_RS and AC2_RS may be formed by performing a dry etching process.

The first recess region AC1_RS may penetrate the first interlayer dielectric layer 110 to extend onto an upper portion of the first source/drain pattern SD1. For example, the first recess region AC1_RS may be formed to be inserted into the first source/drain pattern SD1. The second recess region AC2_RS may penetrate the first interlayer dielectric layer 110 to extend onto an upper portion of the second source/drain pattern SD2. For example, the second recess region AC2_RS may be formed to be inserted into the second source/drain pattern SD2.

Referring back to FIGS. 5A to 5D, first and second active contacts AC1 and AC2 may be formed to penetrate the first interlayer dielectric layer 110 interposed between the capping patterns HMP, thereby being electrically connected to the first and second source/drain patterns SD1 and SD2. A gate contact GC may be formed to penetrate the capping pattern HMP to come into electrical connection with the gate electrode GE.

The formation of the first and second active contacts AC1 and AC2 and the gate contact GC may include forming barrier patterns BM1, BM2, and BM and forming conductive patterns FM1, FM2, and FM on the barrier patterns BM1, BM2, and BM. The barrier patterns BM1, BM2, and BM may be conformally formed and may include a metal layer and a metal nitride layer. The conductive patterns FM1, FM2, and FM may include metal whose resistance is low.

Active contacts may be formed in a self-alignment manner in recess regions formed by using a capping pattern as an etching mask (e.g., hardmask). Therefore, electrical shorts may be suppressed between gates and contacts. In addition, the formation of self-aligned contacts may increase efficiency of fabrication process. Semiconductor devices according to some example embodiments of the present inventive concepts may have improved electrical properties and increased efficiency. Separation structures DB may be formed on first and second boundaries BD1 and BD2 of the single height cell SHC, respectively. The separation structure DB may penetrate the capping pattern HMP and the gate electrode GE to extend into the active pattern AP1 or AP2. The separation structure DB may include a dielectric material, such as a silicon oxide layer or a silicon nitride layer. In some example embodiments, the separation structure DB may include a metallic material.

A second interlayer dielectric layer 120 may be formed on the gate contacts GC and the first and second active contacts AC1 and AC2. A first metal layer M1 may be formed in the second interlayer dielectric layer 120. A third interlayer dielectric layer 130 may be formed on the second interlayer dielectric layer 120. A second metal layer M2 may be formed in the third interlayer dielectric layer 130.

In three-dimensional field effect transistors according to some example embodiments of the present inventive concepts, a polysilicon pattern that constitutes a gate may be formed to have a reduced height, such that the polysilicon pattern may improve in profile failure. In addition, it may be possible to suppress an un-etch issue of source/drain patterns and an un-strip phenomenon of polysilicon patterns when a replacement metal gate process is performed.

In three-dimensional field effect transistors according to some example embodiments of the present inventive concepts, a capping pattern may be used as a hardmask to form a self-aligned contact, and thus electrical shorts may be suppressed between gates and contacts. Thus, an active contact may improve in failure occurring when a self-aligned contact is formed.

Accordingly, some example embodiments of the present inventive concepts may improve profile failure of polysilicon patterns and decrease defects of active contacts, thereby increasing reliability and improving electrical properties of semiconductor devices.

Although the present inventive concepts have been described in connection with the some example embodiments of the present inventive concepts illustrated in the accompanying drawings, it will be understood by one of ordinary skill in the art that variations in form and detail may be made therein without departing from the spirit and essential feature of the present inventive concepts. The above disclosed example embodiments should thus be considered illustrative and not restrictive.

What is claimed is:

1. A semiconductor device, comprising:
a substrate including an active pattern;
a channel pattern on the active pattern, the channel pattern including a plurality of semiconductor patterns that are vertically stacked and spaced apart from each other;
a source/drain pattern connected to the plurality of semiconductor patterns;
a gate electrode on the plurality of semiconductor patterns, the gate electrode including a plurality of inner electrodes between neighboring ones of the plurality of semiconductor patterns and an outer electrode on an uppermost semiconductor pattern; and
a capping pattern on a top surface of the outer electrode,
wherein a line-width of the outer electrode is a first width,
wherein the outer electrode has a first height, and
wherein the first height is equal to or less than the first width.

2. The semiconductor device of claim 1, wherein the first width is in a range of about 5.0 nm to about 30.0 nm.

3. The semiconductor device of claim 1, wherein the first height is in a range of about 10.0 nm to about 12.0 nm.

4. The semiconductor device of claim 1, wherein the capping pattern includes a material having an etch selectivity with respect to silicon oxide.

5. The semiconductor device of claim 4, wherein the capping pattern includes SiN, SiOC, SiOCN, TIN, WC, or a combination thereof.

6. The semiconductor device of claim 1, further comprising:
an active contact electrically connected to the source/drain pattern,
wherein a top surface of the active contact is at a same level as a top surface of the capping pattern.

7. The semiconductor device of claim 1, further comprising:
a gate dielectric layer on a lateral surface and a bottom surface of the outer electrode; and
a gate spacer on the lateral surface of the outer electrode,
wherein the capping pattern covers the top surface of the outer electrode, a top surface of the gate dielectric layer, and a top surface of the gate spacer.

8. The semiconductor device of claim 7, wherein
the outer electrode, the gate dielectric layer, and the gate spacer constitute a gate structure, and
a width in a first direction of the gate structure is same as a width in the first direction of the capping pattern.

9. The semiconductor device of claim 7, wherein
the outer electrode, the gate dielectric layer, and the gate spacer constitute a gate structure, and
a width in a first direction of the gate structure is different from a width in the first direction of the capping pattern.

10. The semiconductor device of claim 9, further comprising:
an active contact electrically connected to the source/drain pattern,
wherein a width in the first direction of the active contact is less than a width in the first direction of the source/drain pattern.

11. The semiconductor device of claim 9, further comprising:
an active contact electrically connected to the source/drain pattern,
wherein the active contact includes,
a body part extending to the top surface of the gate spacer, and
a protrusion part protruding from the body part to the source/drain pattern.

12. A semiconductor device, comprising:
a substrate including an active pattern;
a channel pattern on the active pattern, the channel pattern including a plurality of semiconductor patterns that are vertically stacked and spaced apart from each other;
a source/drain pattern connected to the plurality of semiconductor patterns;
a gate electrode on the plurality of semiconductor patterns, the gate electrode including a plurality of inner electrodes that are between neighboring ones of the plurality of semiconductor patterns;
a gate structure on an uppermost semiconductor pattern from among the semiconductor patterns; and
a capping pattern on the gate structure,
wherein the gate structure includes,
an outer electrode on the uppermost semiconductor pattern,
a gate dielectric layer between the uppermost semiconductor pattern and the outer electrode, the gate dielectric layer extending to a lateral surface of the outer electrode, and
a gate spacer on a lateral surface of the gate dielectric layer, and
wherein the gate structure and the capping pattern are misaligned with each other.

13. The semiconductor device of claim 12, wherein a width in a first direction of the gate structure is same as a width in the first direction of the capping pattern.

14. The semiconductor device of claim 12, wherein
the gate structure has a first center line,
the capping pattern has a second center line, and
the first center line and the second center line are offset from each other.

15. The semiconductor device of claim 12, further comprising:
an interlayer dielectric layer between a plurality of gate structures,
wherein the capping pattern covers a portion of a top surface of the gate structure and a portion of a top surface of the interlayer dielectric layer.

16. The semiconductor device of claim 12, further comprising:
an active contact electrically connected to the source/drain pattern,
wherein the active contact includes,
a body part between a plurality of capping patterns; and
a protrusion part protruding from the body part toward the source/drain pattern, and
wherein a width in a first direction of the body part is greater than a width in the first direction of the protrusion part.

17. The semiconductor device of claim 16, wherein the body part is in contact with a top surface of the gate spacer.

18. A semiconductor device, comprising:
a substrate including an active pattern;
a device isolation layer defining the active pattern;
a channel pattern on the active pattern, the channel pattern including a plurality of semiconductor patterns that are vertically stacked and spaced apart from each other;
a source/drain pattern connected to the plurality of semiconductor patterns;
a gate electrode on the plurality of semiconductor patterns, the gate electrode including a plurality of inner electrodes between neighboring ones of the plurality of semiconductor patterns and an outer electrode on an uppermost one of the semiconductor patterns;
a gate dielectric layer between the gate electrode and each of neighboring ones of the semiconductor patterns;
a gate spacer on a sidewall of the gate electrode;
a capping pattern on a top surface of the outer electrode;
an active contact electrically connected to the source/drain pattern;
a metal-semiconductor compound layer between the active contact and the source/drain pattern;
a first metal layer on the capping pattern, the first metal layer including a power line and a first wiring line electrically connected to the active contact; and
a second metal layer on the first metal layer, the second metal layer including a second wiring line electrically connected to first metal layer,
wherein a top surface of the capping pattern and a top surface of the active contact are substantially coplanar with each other, and
wherein a second height of the capping pattern is equal to or greater than a first height of the outer electrode.

19. The semiconductor device of claim 18, wherein the first height is in a range of about 5.0 nm to about 30.0 nm.

20. The semiconductor device of claim 18, wherein the second height is in a range of about 5.0 nm to about 50.0 nm.
